(19) United States
(12) Patent Application Publication
(10) Pub. No.: US 2025/0284206 A1
(43) Pub. Date: Sep. 11, 2025

(54) MEASUREMENT OF FABRICATION PARAMETERS BASED ON MOIRÉ INTERFERENCE PATTERN COMPONENTS

(71) Applicant: ASML NETHERLANDS B.V., Veldhoven (NL)

(72) Inventors: Xiang HU, Shenzhen (CN); Yu-Jen FAN, Milpitas, CA (US)

(73) Assignee: ASML NETHERLANDS B.V., Veldhoven (NL)

(21) Appl. No.: 18/861,173

(22) PCT Filed: Apr. 26, 2023
(86) PCT No.: PCT/EP2023/060884

§ 371 Date: Oct. 28, 2024

(30) Foreign Application Priority Data
May 20, 2022 (WO) PCT/CN2022/094137

(51) Int. Cl. G03F 7/00

(52) U.S. Cl. CPC G03F 7/70633; G03F 7/70683

(57) ABSTRACT

A method for determination of a parameter of interest in a manufacturing process. For a measurement structure including a first grating with a first pitch and a second grating with a second pitch, a sensitivity of a Moiré interference pattern component is determined. The sensitivity is determined with respect to the parameter of interest in the manufacturing process. The measurement structure is evaluated, based on the sensitivity, for use in measuring the parameter of interest in the manufacturing process. A method of measuring the parameter of interest based on the measurement structure is described. A method of generating parameters of the measurement structure based on evaluation of the measurement structure for measurement of the parameter of interest is also described.

### CROSS-REFERENCE TO RELATED APPLICATIONS

This application claims priority of PCT application PCT/CN2022/094137 which was filed on 20 May 2022 and which is incorporated herein in its entirety by reference.

### TECHNICAL FIELD

The present disclosure relates generally measurement of parameters of interest in semiconductor manufacturing and more specifically to measurement based on Moiré interference pattern components.

### BACKGROUND

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc. Patterning can occur in multiple layers, such that a multi-layer stack or device can be constructed from a set of patterned layers which are aligned with one another during patterning and other steps.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electromechanical systems (MEMS) and other devices.

As semiconductor manufacturing processes continue to advance, the dimensions of functional elements have continually been reduced. At the same time, the number of functional elements, such as transistors, per device has been steadily increasing, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, which can include alignment tools, the design layout, or the patterning device.

Monitoring of device and material features, including CD, and of parameters of interest in a manufacturing process (e.g., fabrication parameters such as overlay offset, dose, symmetry, etc.), allows for process monitoring, control, and correction, including control of lithography and other fabrication steps. A metrology apparatus can be used to determine properties of devices and how properties of different devices vary or how properties associated with different layers of the same device vary from layer to layer. The metrology apparatus, which can be a diffraction-based apparatus, an optical apparatus, an electron microscopy apparatus, etc., may alternatively be constructed to identify defects on the device or to align the device and may, for example, be part of the lithographic apparatus or may be a stand-alone device. The metrology apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

### SUMMARY

In one embodiment, a method comprising: determining, for a measurement structure comprising a first grating with a first pitch and a second grating with a second pitch, a sensitivity of a Moiré interference pattern component with respect to a parameter of interest in a manufacturing process; and evaluating the measurement structure for use in measuring the parameter of interest in the manufacturing process based on the sensitivity.

In a further embodiment, wherein the determining of the sensitivity comprises determining a sensitivity as a function of at least one of the first pitch, the second pitch, or a combination thereof.

In a further embodiment, wherein the evaluating of the measurement structure comprises: determining if a phase of the Moiré interference pattern component is substantially linear with respect to the parameter of interest in the manufacturing process.

In a further embodiment, wherein the evaluating of the measurement structure comprises: determining if a phase of the Moiré interference pattern component is substantially constant with respect to the parameter of interest in the manufacturing process over a range of wavelengths.

In a further embodiment, wherein the Moiré interference pattern component comprises a Moiré interference pattern component at a Moiré pitch.

In a further embodiment, wherein the Moiré interference pattern component comprises a Moiré interference pattern component at a pitch smaller than a Moiré pitch.

In a further embodiment, wherein the Moiré interference pattern component comprises a Moiré interference pattern component at a pitch larger than a Moiré pitch.

In one embodiment, a method comprising: obtaining a Moiré interference pattern for a measurement structure, wherein the measurement structure comprises a first grating at a first pitch in a first layer and a second grating at a second pitch in a second layer; identifying a Moiré interference pattern component in the measured Moiré interference pattern; and determining a measurement of a parameter of interest in a manufacturing process based on the Moiré interference pattern component.

In a further embodiment, further comprising: identifying a second Moiré interference pattern component in the Moiré interference pattern; and determining a measurement of the parameter of interest in the manufacturing process based on the Moiré interference pattern component and the second Moiré interference pattern component.

In a further embodiment, wherein the Moiré interference pattern component comprises a component of the Moiré interference pattern with a first frequency and wherein the second Moiré interference pattern component comprises a component of the Moiré interference pattern with a second frequency.

In one embodiment, a method comprising: determining a Moiré interference pattern component for a measurement structure, wherein the measurement structure comprises a first grating at a first pitch in a first layer and a second grating at a second pitch in a second layer; obtaining a Moiré pattern for the measurement structure; removing the determined Moiré interference pattern component from the Moiré interference pattern; and determining a measure of a parameter of interest in a manufacturing process based on the Moiré pattern with the Moiré interference pattern component removed.

In one embodiment, a method comprising: generating parameters for at least one measurement structure, wherein the at least one measurement structure comprises a first grating at a first pitch in a first layer of a multi-layer stack structure and a second grating at a second pitch in a second layer of the multi-layer stack structure, wherein the first pitch and the second pitch are determined based on evaluating the at least one measurement structure for measurement of a parameter of interest in a manufacturing process, wherein the generating of the parameters for the at least one measurement structure comprises, determining, for the at least one measurement structure, a sensitivity of a Moiré interference pattern component with respect to measurement of the parameter of interest in the manufacturing process; and evaluating the at least one measurement structure for use in measuring the parameter of interest in the manufacturing process based on the sensitivity.

In a further embodiment, wherein the generating of the parameters for the at least one measurement structure further comprises: determining if the evaluation of at least one measurement structure for use in measuring the parameter of interest in the manufacturing process is unfavorable; and based on a determination that the evaluation is unfavorable, adjusting at least one parameter of the at least one measurement structure to generate at least one adjusted measurement structure.

In a further embodiment, further comprising: obtaining a Moiré interference pattern for the at least one measurement structure; identifying the Moiré interference pattern component in the Moiré interference pattern; identifying the second Moiré interference pattern component in the Moiré interference pattern; and determining a measure of the parameter of interest in the manufacturing process for the at least one measurement structure based on a relationship between the Moiré interference pattern component and the second Moiré interference pattern component.

In one embodiment, a machine-readable medium having instructions thereon, the instructions when executed by a processor being configured to perform the method of another embodiment.

In a further embodiment, a processor and a machine readable medium as described in another embodiment.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts, and in which:

FIG. 1 depicts a schematic overview of a lithographic apparatus, according to an embodiment.

FIG. 2 depicts a schematic overview of a lithographic cell, according to an embodiment.

FIG. 3 depicts a schematic representation of holistic lithography, representing a cooperation between three technologies to optimize semiconductor manufacturing, according to an embodiment.

FIG. 4 illustrates an example metrology apparatus, according to an embodiment.

FIG. 5 depicts a schematic representation of a measurement structure comprising a first grating with a first pitch and a second grating with a second pitch, according to an embodiment.

FIG. 6A illustrates a Moiré interference pattern for an example measurement structure comprising a first grating with a first pitch and a second grating with a second pitch with an overlay offset of zero, according to an embodiment.

FIG. 6B depicts a Moiré interference pattern for the example measurement structure of FIG. 6A with a nonzero overlay offset, according to an embodiment.

FIG. 7 depicts a graph of intensity of a Moiré interference pattern measured in the x-y plane for a measurement structure with contributions from Moiré interference pattern components at various frequencies, according to an embodiment.

FIG. 8 depicts a graph of intensity of a Moiré interference pattern along a cross section in the direction x of FIG. 7, according to an embodiment.

FIG. 9 depicts a graph of components of the Moiré interference pattern of the cross-sectional intensity of FIG. 8 as a function of frequency, according to an embodiment.

FIG. 10 depicts a schematic illustration of scattering in a measurement structure comprising a grating with a first pitch and a second grating with a second pitch, according to an embodiment.

FIG. 11 illustrates an exemplary method for evaluation of a Moiré interference pattern component for measurement of a parameter of interest in a manufacturing process, according to an embodiment.

FIG. 12 depicts a graph of intensity of a Moiré interference pattern component in the x-y plane for a measurement structure, according to an embodiment.

FIGS. 13A and 13B depicts graphs of intensity for Moiré interference patterns and extracted Moiré interference pattern components along cross sections in the direction x of FIG. 12, according to an embodiment.

FIG. 14 illustrates an interference pattern for an example measurement structure comprising a first pitch, a second pitch, and a third pitch, according to an embodiment.

FIG. 15 illustrates an exemplary method for generation of a measurement structure for measurement of a parameter of interest in a manufacturing process based on multiple Moiré interference pattern components, according to an embodiment.

FIG. 16 illustrates an exemplary method for determination of a parameter of interest in a manufacturing process based on multiple Moiré interference pattern components, according to an embodiment.

FIG. 17A illustrates an example grating comprising interlaced gratings, according to an embodiment.

FIG. 17B illustrates an example grating comprising non-overlapping interlaced gratings, according to an embodiment.

FIG. 18 illustrates an example grating comprising perpendicularly segmented interlaced gratings, according to an embodiment.

FIG. 19 illustrates an example measurement structure comprising a grating with a varied pitch, according to an embodiment.

FIG. 20 illustrates an example measurement structure comprising a grating with interspersed areas of different pitches, according to an embodiment.

FIG. 21 illustrates an example measurement structure comprising gratings with resolvable pitches, according to an embodiment.

FIG. 22 illustrates an example measurement structure for measurement of a parameter of interest in the manufacturing process based on components of the Moiré interference pattern, according to an embodiment.

FIGS. 23A and 23B illustrate Moiré interference patterns for the measurement structure of FIG. 22, according to an embodiment.

FIG. 24 illustrates an example two-dimensional measurement structure, according to an embodiment.

FIG. 25 illustrates a Moiré interference pattern for the measurement structure of FIG. 24, according to an embodiment.

FIG. 26 illustrates a Fourier transform of the Moiré interference pattern of FIG. 25, according to an embodiment.

FIG. 27 is a block diagram of an example computer system, according to an embodiment of the present disclosure.

### DETAILED DESCRIPTION

Embodiments of the present disclosure are described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

A (e.g., semiconductor) patterning device can comprise, or can form, one or more patterns. The pattern can be generated utilizing CAD (computer-aided design) programs, based on a pattern or design layout, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include and/or specify specific parameters, limits on and/or ranges for parameters, and/or other information. One or more of the design rule limitations and/or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

As used herein, the term “patterning process” generally means a process that creates an etched substrate by the application of specified patterns of light as part of a lithography process. However, “patterning process” can also include (e.g., plasma) etching, as many of the features described herein can provide benefits to forming printed patterns using etch (e.g., plasma) processing.

As used herein, the term “pattern” means an idealized pattern that is to be etched on a substrate (e.g., wafer)—e.g., based on the design layout described above. A pattern may comprise, for example, various shape(s), arrangement(s) of features, contour(s), etc.

As used herein, a “printed pattern” means the physical pattern on a substrate that was etched based on a target pattern. The printed pattern can include, for example, troughs, channels, depressions, edges, or other two- and three-dimensional features resulting from a lithography process.

As used herein, the term “prediction model”, “process model”, “electronic model”, and/or “simulation model” (which may be used interchangeably) means a model that includes one or more models that simulate a patterning process. For example, a model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), an OPC model (e.g., that can be used to make target patterns and may include sub-resolution resist features (SRAFs), etc.), an etch (or etch bias) model (e.g., that simulates the physical effects of an etching process on a printed wafer pattern), a source mask optimization (SMO) model, and/or other models.

As used herein, the term “calibrating” means to modify (e.g., improve or tune) and/or validate a model, an algorithm, and/or other components of a present system and/or method.

A patterning system may be a system comprising any or all of the components described above, plus other components configured to performing any or all of the operations associated with these components. A patterning system may include a lithographic projection apparatus, a scanner, systems configured to apply and/or remove resist, etching systems, and/or other systems, for example.

As used herein, the term “diffraction” refers to the behavior of a beam of light or other electromagnetic radiation when encountering an aperture or series of apertures, including a periodic structure or grating. “Diffraction” can include both constructive and destructive interference, including scattering effects and interferometry. As used herein, a “grating” is a periodic structure, which can be one-dimensional (i.e., comprised of posts of dots), two-dimensional, or three-dimensional, and which causes optical interference, scattering, or diffraction. A “grating” can be a diffraction grating.

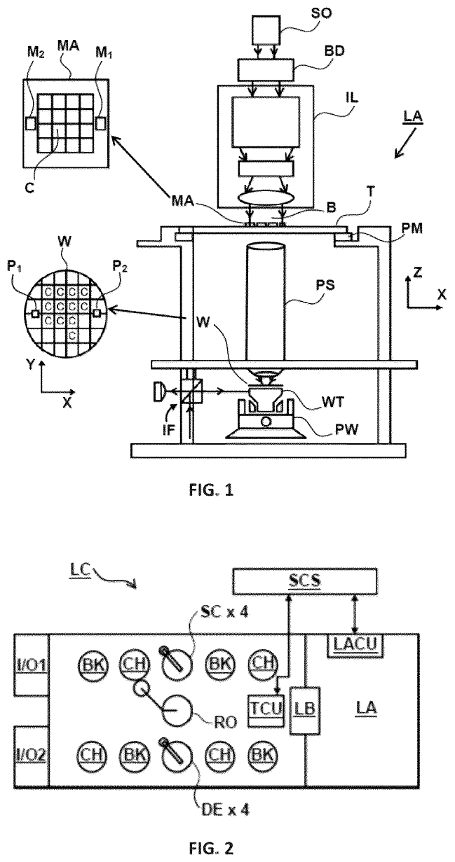

As a brief introduction, FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) T constructed to support a patterning device (e.g., a mask) MA and connected to a first positioner PM configured to accurately position the patterning device MA in accordance with certain parameters, a substrate support (e.g., a wafer table) WT configured to hold a substrate (e.g., a resist coated wafer) W and coupled to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g., via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g., mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

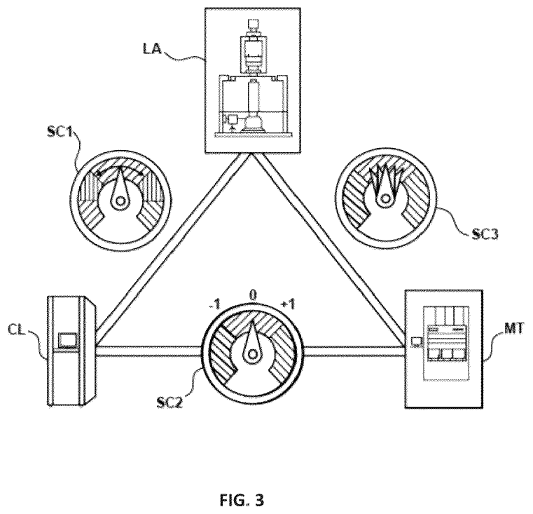

FIG. 2 depicts a schematic overview of a lithographic cell LC. As shown in FIG. 2 the lithographic apparatus LA may form part of lithographic cell LC, also sometimes referred to as a lithocell or (litho)cluster, which often also includes apparatus to perform pre- and post-exposure processes on a substrate W. Conventionally, these include spin coaters SC configured to deposit resist layers, developers DE to develop exposed resist, chill plates CH and bake plates BK, e.g. for conditioning the temperature of substrates, W e.g., for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g., via lithography control unit LACU.

In order for the substrates W (FIG. 1) exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W (FIG. 1), and, in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

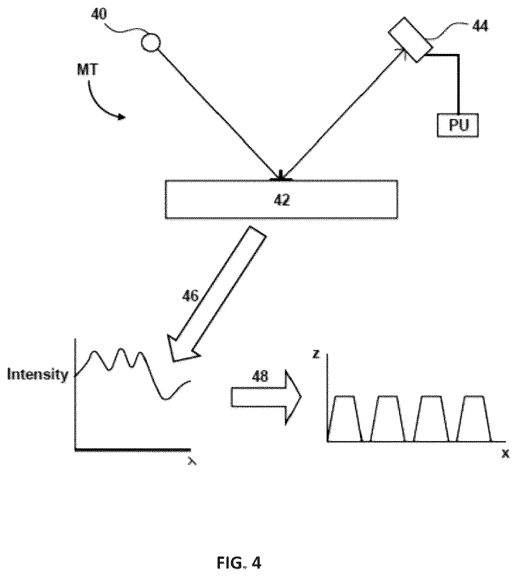

FIG. 3 depicts a schematic representation of holistic lithography, representing a cooperation between three technologies to optimize semiconductor manufacturing. Typically, the patterning process in a lithographic apparatus LA is one of the most critical steps in the processing which requires high accuracy of dimensioning and placement of structures on the substrate W (FIG. 1). To ensure this high accuracy, three systems (in this example) may be combined in a so called “holistic” control environment as schematically depicted in FIG. 3. One of these systems is the lithographic apparatus LA which is (virtually) connected to a metrology apparatus (e.g., a metrology tool) MT (a second system), and to a computer system CL (a third system). A “holistic” environment may be configured to optimize the cooperation between these three systems to enhance the overall process window and provide tight control loops to ensure that the patterning performed by the lithographic apparatus LA stays within a process window. The process window defines a range of process parameters (e.g., dose, focus, overlay) within which a specific manufacturing process yields a defined result (e.g., a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g., using input from the metrology tool MT) to predict whether defects may be present due to, for example, sub-optimal processing (depicted in FIG. 3 by the arrow pointing “0” in the second scale SC2).

The metrology apparatus (tool) MT may provide input to the computer system CL to enable accurate simulations and predictions, and may provide feedback to the lithographic apparatus LA to identify possible drifts, e.g., in a calibration status of the lithographic apparatus LA (depicted in FIG. 3 by the multiple arrows in the third scale SC3).

In lithographic processes, it is desirable to make frequent measurements of the structures created, e.g., for process control and verification. Different types of metrology tools MT for making such measurements are known, including scanning electron microscopes or various forms of optical metrology tool, image based or scatterometery-based metrology tools. Scatterometers are versatile instruments which allow measurements of the parameters of a lithographic process by having a sensor in the pupil or a conjugate plane with the pupil of the objective of the scatterometer, measurements usually referred as pupil-based measurements, or by having the sensor in the image plane or a plane conjugate with the image plane, in which case the measurements are usually referred as image or field-based measurements. Such scatterometers and the associated measurement techniques are further described in patent applications US20100328655, US2011102753A1, US20120044470A, US20110249244, US20110026032 or EP1,628,164A, incorporated herein by reference in their entirety. Aforementioned scatterometers may measure features of a substrate such as gratings using light from soft x-ray and visible to near-IR wavelength range, for example.

In some embodiments, a scatterometer MT is an angular resolved scatterometer. In these embodiments, scatterometer reconstruction methods may be applied to the measured signal to reconstruct or calculate properties of a grating and/or other features in a substrate. Such reconstruction may, for example, result from simulating interaction of scattered radiation with a mathematical model of the target structure and comparing the simulation results with those of a measurement. Parameters of the mathematical model are adjusted until the simulated interaction produces a diffraction pattern similar to that observed from the real target.

In some embodiments, scatterometer MT is a spectroscopic scatterometer MT. In these embodiments, spectroscopic scatterometer MT may be configured such that the radiation emitted by a radiation source is directed onto target features of a substrate and the reflected or scattered radiation from the target is directed to a spectrometer detector, which measures a spectrum (i.e., a measurement of intensity as a function of wavelength) of the specular reflected radiation. From this data, the structure or profile of the target giving rise to the detected spectrum may be reconstructed, e.g., by Rigorous Coupled Wave Analysis and non-linear regression or by comparison with a library of simulated spectra.

In some embodiments, scatterometer MT is an ellipsometric scatterometer. The ellipsometric scatterometer allows for determining parameters of a lithographic process by measuring scattered radiation for each polarization states. Such a metrology apparatus (MT) emits polarized light (such as linear, circular, or elliptic) by using, for example, appropriate polarization filters in the illumination section of the metrology apparatus. A source suitable for the metrology apparatus may provide polarized radiation as well. Various embodiments of existing ellipsometric scatterometers are described in U.S. patent application Ser. Nos. 11/451,599, 11/708,678, 12/256,780, 12/486,449, 12/920,968, 12/922,587, 13/000,229, 13/033,135, 13/533,110 and 13/891,410 incorporated herein by reference in their entirety.

In some embodiments, scatterometer MT is adapted to measure the overlay of two misaligned gratings or periodic structures (and/or other target features of a substrate) by measuring asymmetry in the reflected spectrum and/or the detection configuration, the asymmetry being related to the extent of the overlay. The two (typically overlapping) grating structures may be applied in two different layers (not necessarily consecutive layers), and may be formed substantially at the same position on the wafer. The scatterometer may have a symmetrical detection configuration as described e.g., in patent application EP1,628,164A, such that any asymmetry is clearly distinguishable. This provides a way to measure misalignment in gratings. Further examples for measuring overlay may be found in PCT patent application publication no. WO 2011/012624 or US patent application US 20160161863, incorporated herein by reference in their entirety.

Focus and dose used in lithography process may be determined by scatterometry (or alternatively by scanning electron microscopy) as described in US patent application US2011-0249244, incorporated herein by reference in its entirety. A single structure (e.g., feature in a substrate) may be used which has a unique combination of critical dimension and sidewall angle measurements for each point in a focus energy matrix (FEM—also referred to as Focus Exposure Matrix). If these unique combinations of critical dimension and sidewall angle are available, the focus and dose values may be uniquely determined from these measurements.

A metrology target may be an ensemble of composite gratings and/or other features in a substrate, formed by a lithographic process, commonly in resist, but also after etch processes, for example. Typically, the pitch and linewidth of the structures in the gratings depend on the measurement optics (in particular the NA of the optics) to be able to capture diffraction orders coming from the metrology targets. A diffracted signal may be used to determine shifts between two layers (also referred to “overlay”) or may be used to reconstruct at least part of the original grating as produced by the lithographic process. This reconstruction may be used to provide guidance of the quality of the lithographic process and may be used to control at least part of the lithographic process.

Targets may have smaller sub-segmentation which are configured to mimic dimensions of the functional part of the design layout in a target. Due to this sub-segmentation, the targets will behave more similarly to the functional part of the design layout such that the overall process parameter measurements resemble the functional part of the design layout. The targets may be measured in an underfilled mode or in an overfilled mode. In the underfilled mode, the measurement beam generates a spot that is smaller than the overall target. In the overfilled mode, the measurement beam generates a spot that is larger than the overall target. In such overfilled mode, it may also be possible to measure different targets simultaneously, thus determining different processing parameters at the same time.

Overall measurement quality of a lithographic parameter using a specific target is at least partially determined by the measurement recipe used to measure this lithographic parameter. The term “substrate measurement recipe” may include one or more parameters of the measurement itself, one or more parameters of the one or more patterns measured, or both. For example, if the measurement used in a substrate measurement recipe is a diffraction-based optical measurement, one or more of the parameters of the measurement may include the wavelength of the radiation, the polarization of the radiation, the incident angle of radiation relative to the substrate, the orientation of radiation relative to a pattern on the substrate, etc. One of the criteria to select a measurement recipe may, for example, be a sensitivity of one of the measurement parameters to processing variations. More examples are described in US patent application US2016-0161863 and published US patent application US 2016/0370717A1 incorporated herein by reference in its entirety.

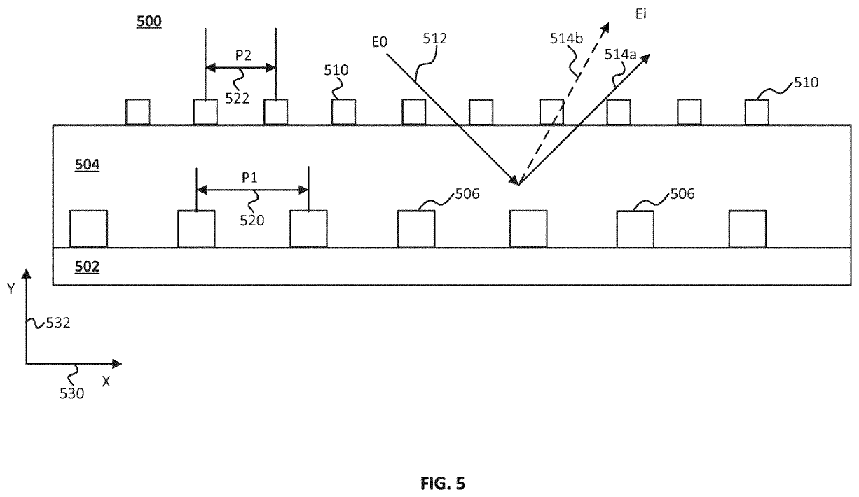

FIG. 4 illustrates an example metrology apparatus (tool) MT, such as a scatterometer. MT comprises a broadband (white light) radiation projector 40 which projects radiation onto a substrate 42. The reflected or scattered radiation is passed to a spectrometer detector 44, which measures a spectrum 46 (i.e., a measurement of intensity as a function of wavelength) of the specular reflected radiation. From this data, the structure or profile giving rise to the detected spectrum may be reconstructed 48 by processing unit PU, e.g., by Rigorous Coupled Wave Analysis and non-linear regression or by comparison with a library of simulated spectra as shown at the bottom of FIG. 4. In general, for the reconstruction, the general form of the structure is known and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer, for example.

It is often desirable to be able computationally determine how a patterning process would produce a desired pattern on a substrate. Computational determination may comprise simulation and/or modeling, for example. Models and/or simulations may be provided for one or more parts of the manufacturing process. For example, it is desirable to be able to simulate the lithography process of transferring the patterning device pattern onto a resist layer of a substrate as well as the yielded pattern in that resist layer after development of the resist, simulate metrology operations such as the determination of overlay, and/or perform other simulations. The objective of a simulation may be to accurately predict, for example, metrology metrics (e.g., overlay, a critical dimension, a reconstruction of a three dimensional profile of features of a substrate, a dose or focus of a lithography apparatus at a moment when the features of the substrate were printed with the lithography apparatus, etc.), manufacturing process parameters (e.g., edge placements, aerial image intensity slopes, sub resolution assist features (SRAF), etc.), and/or other information which can then be used to determine whether an intended or target design has been achieved. The intended design is generally defined as a pre-optical proximity correction design layout which can be provided in a standardized digital file format such as GDSII, OASIS or another file format.

Simulation and/or modeling can be used to determine one or more metrology metrics (e.g., performing overlay and/or other metrology measurements), configure one or more features of the patterning device pattern (e.g., performing optical proximity correction), configure one or more features of the illumination (e.g., changing one or more characteristics of a spatial/angular intensity distribution of the illumination, such as change a shape), configure one or more features of the projection optics (e.g., numerical aperture, etc.), and/or for other purposes. Such determination and/or configuration can be generally referred to as mask optimization, source optimization, and/or projection optimization, for example. Such optimizations can be performed on their own, or combined in different combinations. One such example is source-mask optimization (SMO), which involves the configuring of one or more features of the patterning device pattern together with one or more features of the illumination. The optimizations may use the parameterized model described herein to predict values of various parameters (including images, etc.), for example.

In some embodiments, an optimization process of a system may be represented as a cost function. The optimization process may comprise finding a set of parameters (design variables, process variables, etc.) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics. The cost function can also be the maximum of these deviations (i.e., worst deviation). The term “evaluation points” should be interpreted broadly to include any characteristics of the system or fabrication method. The design and/or process variables of the system can be confined to finite ranges and/or be interdependent due to practicalities of implementations of the system and/or method. In the case of a lithographic projection apparatus, the constraints are often associated with physical properties and characteristics of the hardware such as tunable ranges, and/or patterning device manufacturability design rules. The evaluation points can include physical points on a resist image on a substrate, as well as non-physical characteristics such as dose and focus, for example.

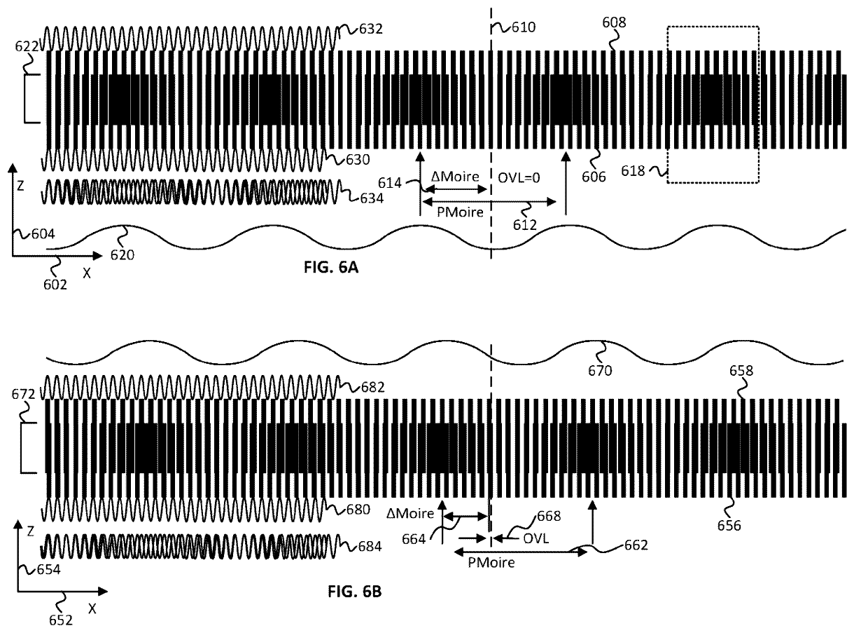

FIG. 5 depicts a schematic representation of a measurement structure comprising a first grating with a first pitch and a diffraction grating with a second pitch. A measurement structure 500 can be a measurement structure used with a metrology apparatus, which can be a specialized metrology apparatus such as a diffraction metrology apparatus, or can be a general metrology apparatus, such as a camera or imager. The measurement structure 500 comprises a substrate 502, a first grating 506, a stack medium 504, and a second grating 510. The first grating 506 can be a diffraction grating and the second grating 510 can be a diffraction grating. The substrate 502 can be a semiconductor substrate, a conductive substrate, an insulating substrate, etc. The substrate 502 can be a physical substrate, such as a silicon wafer, upon which one or more electronic device is fabricated. The substrate 502 can instead be any layer upon which the first grating 506 is fabricated, such as a previously fabricated portion of an electronic device.

The stack medium 504 may comprise one or more layer, including stacked layers, self-assembled layers, depositional layers, oxide layers, etc. The stack medium 504 can have material and electronic properties, such as refractive index, density, lattice constant, resistivity, etc., which are constant, which change linearly, which are discontinuous, etc. The material and electronic properties of the stack medium 504 may depend on its stack structure or fabrication methods. The stack medium 504 can comprise a medium with a refractive index greater than one.

The first grating 506 can comprise any periodic structure with a first pitch 520 (e.g., P1). The first pitch 520 can be measured in a period, a frequency, etc. and may correspond to a wavelength. The first grating 506 can comprise a periodic arrangement of rectilinear elements, triangular elements, rectangular prism elements, etc. The first grating 506 can comprise a periodic arrangement of elements of the same size as the spacing between the elements or of a different size than the spacing between the elements. The first grating 506 can be fabricated by one or more depositional processes, lithographic processes, etching processes, or a combination thereof. The first grating 506 can be composed of one or more materials. For example, the first grating can be a metal or comprise a metal layer, such as a titanium adhesion layer and a gold layer. The first grating 506 can instead or additional comprise a semiconducting material, an insulating material, a conducting material, etc.

The second grating 510 can comprise any periodic structure with a second pitch 522 (e.g., P2).

The second pitch 522 can be measured in a period, a frequency, etc. and may correspond to a wavelength. The second pitch 522 can be different from the first pitch 520. The second pitch 522 can be larger or smaller than the first pitch 520. The second pitch 522 can be a fraction or multiple of the first pitch 520, such that the first pitch 520 and the second pitch 522 have a least common multiple.

The first pitch 520 and the second pitch 522 can comprise a periodic cell or supercell, which can contain integer multiples of the first pitch 520 and the second pitch 522. The second grating 510 can comprise a periodic arrangement of rectilinear elements, triangular elements, rectangular prism elements, etc. which are the same or different than the elements of the periodic arrangement of the first grating 506. The second grating 510 can comprise a periodic arrangement of elements of the same size as the spacing between the elements or of a different size than the spacing between the elements. The elements of the first grating 506 and the second grating 510 can overlap in a direction perpendicular to a plane of the gratings (i.e., a y direction 532). Alternatively, the elements of the first grating 506 and the second grating 510 may not overlap in y direction 532. The second grating 510 can be fabricated by one or more depositional processes, lithographic processes, etching processes, or a combination thereof. The fabrication processes which produce the second grating 510 can be the same or different than the fabrication processes which produce the first grating 506. The second grating 510 can be composed of one or more materials. The second grating 510 can instead or additional comprise a semiconducting material, an insulating material, a conducting material, etc. The second grating 510 can be the same or a different material than the first grating 506. The second grating 510 can be coated or otherwise covered with one or more additional layers. The second grating 510 can also be exposed to air, an inert gas, covered in oil, or otherwise prepared for optical or other measurements.

The measurement structure 500 may be subjected to incident electromagnetic radiation 512 in order to measure one or more characteristics of the measurement structure 500. The incident electromagnetic radiation 512 can be of a specific wavelength or phase, for example laser light, or can be of a range of wavelengths or phases including collimated light, white light, UV light, EUV light, etc. The incident electromagnetic radiation 512 can approach the measurement structure 500 obliquely, as shown, at a high angle to the substrate, at a low angle to the substrate, perpendicular to the substrate, etc. The incident electromagnetic radiation 512 can produce outgoing electromagnetic radiation 514a, 514b. The outgoing electromagnetic radiation 514a, 514b can comprise reflected electromagnetic radiation, diffracted electromagnetic radiation, emitted electromagnetic radiation, or a combination thereof. The outgoing electromagnetic radiation 514a, 514b can be scattered radiation, where the scattering mechanism can vary. The outgoing electromagnetic radiation 514a, 514b can comprise an electromagnetic signal which can vary in wavelength, phase, intensity, polarization, etc. as a function of angle of incidence, azimuthal angle, distance, etc. from the measurement structure 500 or a source of the incident electromagnetic radiation 512. The outgoing electromagnetic radiation 514a, 514b can have the same or different wavelengths as the incident electromagnetic radiation 512.

The outgoing electromagnetic radiation 514a, 514b can be measured at a detector.

The first grating 506 and the second grating 510 can be offset by the stack medium 504 in a y direction 532 (which may be the direction of fabrication). The first grating 506 and the second grating 510 can also be offset in an x-y plane—which may be substantially orthogonal to the direction of fabrication—where layers of the measurement structure 500 are overlayed upon one another. An overlay offset can be measured in a x-direction 530 where the overlay offset is a measure of the deviation of the overlay from an ideal overlay as determined. The overlay offset can be determined based on a difference between the measurement structure 500 or an electromagnetic signal generated using the measurement structure 500 and an ideal measurement structure 500 or an electromagnetic signal corresponding to an ideal measurement structure 500.

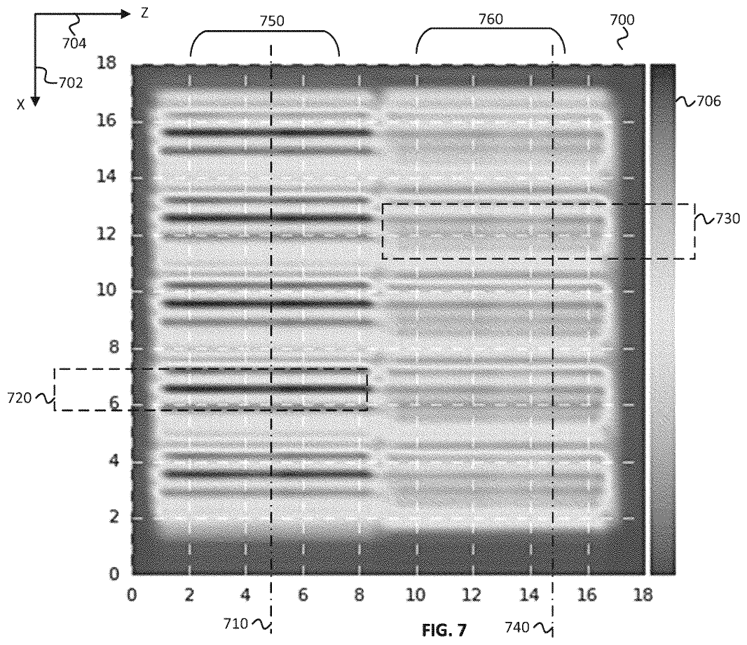

FIG. 6A illustrates a Moiré interference pattern for an example measurement structure comprising a first grating with a first pitch and a second grating with a second pitch with an overlay offset of zero. A Moiré interference pattern, also called a Moiré fringe or Moiré pattern, is an interference pattern arising from the interaction of two or more patterns, which may be periodic or quasi-periodic in nature, and which have transparent or semi-transparent portions and are at least slightly distorted from one another. A measurement structure comprising a first grating with a first pitch and a second grating with a second pitch, where the first pitch and the second pitch are not identical, can create a Moiré interference pattern. The Moiré interference pattern between two pitches, a first pitch 606 and a second pitch 608 is depicted in region 622 as a function of an x-direction 602 and a z-direction 604. The grating with the first pitch 606 and the grating with the second pitch 608 are depicted as offset in the z-direction 604 in order to show both gratings and the first pitch 606 and the second pitch 608, however such an offset in the z-direction 604 may not be present in a measurement structure. The interaction of the first pitch 606 and the second pitch 608 produces a Moiré interference pattern with areas or greater intensity, such as the local maximum in intensity depicted in a box 618, and areas of lesser intensity. The intensity of the Moiré interference pattern is represented by a sinusoidal curve 620 with a Moiré period 612. The location of the local maxima and minimum in the Moiré interference pattern (e.g., the phase of the Moiré interference pattern) can be used to measure overlay offset or another parameter of interest in the manufacturing process. For a reference point with respect to either the first pitch 606 or the second pitch 608 (which can be a midpoint, an endpoint, a distance, etc.) a Moiré phase shift 614 can be determined. FIG. 6A illustrates a measurement structure for which the overlay offset is zero, (e.g., an ideal measurement structure).

The Moiré interference pattern can also be depicted based on a sinusoidal representation of the first pitch 606 and the second pitch 608. The first pitch 606 can be represented as a first sinusoidal intensity 630 with the same frequency as the first pitch 606, while the second pitch 608 can be represented by a second sinusoidal intensity 632 with the same frequency as the second pitch 608. An overlay 634 of the first sinusoidal intensity 630 and the second sinusoidal intensity 632 shows a relationship to the Moiré interference pattern, which corresponds to regions of greater and lesser intensity in the combination of the first sinusoidal intensity 630 and the second sinusoidal intensity 632.

FIG. 6B depicts a Moiré interference pattern for the example measurement structure of FIG. 6A with a nonzero overlay offset. The Moiré interference pattern between two pitches, a first pitch 656 which has the same periodicity as the first pitch 606 of FIG. 6A and a second pitch 658 which has the same periodicity as the second pitch 608 of FIG. 6B, is depicted in region 672 as a function of an x-direction 652 and a z-direction 654. Again, the grating with the first pitch 656 and the grating with the second pitch 658 are depicted as offset in the z-direction 654 for illustrative purposes. The first pitch 656 is also offset in the x-direction 652 relative to the second pitch 658 by an overlay offset 668, when compared to FIG. 6A. As the first pitch 656 is not equal to the second pitch 658, the individual elements which make up the pitches display offset over a majority of the region 672. A line 610 is used to mark a reference point from which measurements of overlay offset can be made. However, the offset of the first pitch 656 relative to the second pitch 658 in FIG. 6B is different than the offset of the first pitch 606 and the second pitch 608 in FIG. 6B.

The intensity of the Moiré interference pattern is represented by a sinusoidal curve 670 with a Moiré period 662. The location of the local maxima and minimum in the Moiré interference pattern (e.g., the phase of the Moiré interference pattern) are shifted due to the overlay offset 668, relative to the phase of the Moiré pattern in FIG. 6A. The overlay offset 668 is shown as a shift with reference to the line 610, but can be measured relative to any appropriate reference point. For a reference point with respect to either the first pitch 606 or the second pitch 608 (which can be a midpoint, an endpoint, a distance, etc.) a Moiré phase shift 664 can be determined. From the Moiré phase shift 614 of FIG. 6A and the Moiré phase shift 664 of FIG. 6B, a change in the phase of the Moiré pattern can be determined. From the change in the Moiré pattern, the overlay offset 668 can be determined.

The Moiré interference pattern can again be depicted based on a sinusoidal representation of the first pitch 656 and the second pitch 658. The first pitch 656 can be represented as a first sinusoidal intensity 680 with the same frequency as the first pitch 656 (and the first pitch 606 of FIG. 6A), while the second pitch 658 can be represented by a second sinusoidal intensity 682 with the same frequency as the second pitch 658 (and the second pitch 608 of FIG. 6A). An overlay 684 of the first sinusoidal intensity 680 and the second sinusoidal intensity 682 shows a relationship to the Moiré interference pattern, which corresponds to regions of greater and lesser intensity in the combination of the first sinusoidal intensity 680 and the second sinusoidal intensity 682.

The Moiré pitch, which is a representation of a periodicity of the Moiré interference pattern, can be determined by a relationship between the first pitch and the second pitch, such as by using Equation 1, below:

$$Moire Pitch = \frac{{P}_{1} {P}_{2}}{\vert {P}_{1} - {P}_{2} \vert} \qquad ( 1 )$$

where P₁ is the first pitch and P₂ is the second pitch. For at least a semi-transparent (to incident radiation) measurement, the first pitch can represent the buried pitch or the exposed pitch while the second pitch can be the other pitch for a two-pitch measurement structure. For simplicity, the buried pitch is referred to herein as the first pitch, as it is generally fabricated first, but either pitch can be the buried pitch and the pitches can be fabricated in either order. The Moiré pitch can be the greatest pitch of the Moiré interference pattern (e.g., the lowest frequency component of the Moiré interference pattern).

The Moiré phase shift, which is the relationship between the overlay offset and the phase shift in the Moiré pattern, can also be given by a relationship between the first pitch and the second pitch, using Equation 2, below:

$$Moire Phase Shift = OVL \frac{{P}_{1}}{{P}_{1} - {P}_{2}} \qquad ( 2 )$$

Where OVL is the overlay offset caused by the shift in the first pitch, P₁ is the first pitch and P₂ is the second pitch. A similar relationship can be determined for the shift in the second pitch. The Moiré phase shift, for first pitches and second pitches which are close in size but not identical, can therefore be larger than the actual OVL by a multiplicative factor. By selecting a first pitch and a second pitch, the Moiré phase shift can be selected which is larger than the overlay offset and correspondingly easier to measure for elements which small (e.g., on the order of CD for ICs). The relationship between the overlay offset and the Moiré phase shift can be linear, which allows for direct determination of the overlay offset based on the Moiré phase shift relative to a reference (e.g., zero overlay offset) Moiré phase shift.

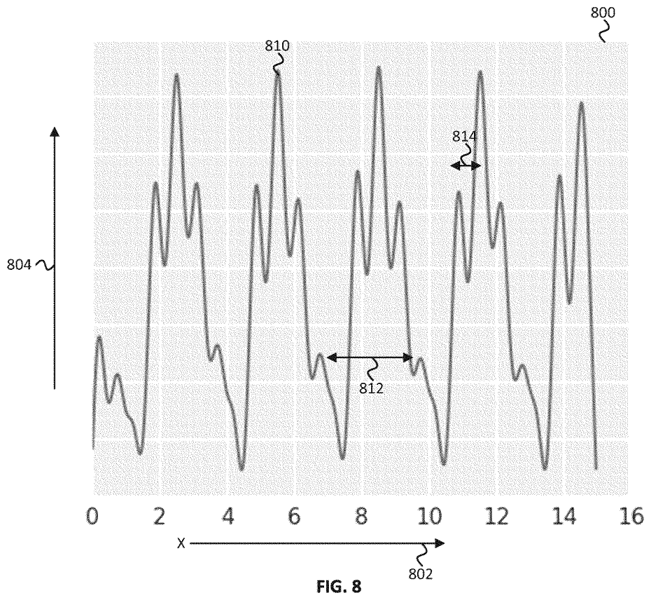

FIG. 7 depicts a graph of intensity of a Moiré interference pattern measured in the x-y plane for a measurement structure with contributions from Moiré interference pattern components at various frequencies. A graph 700 depicts an example Moiré interference pattern for two measurement structures, where a first measurement structure is indicated by parenthesis 750 and a second measurement structure is indicated by parenthesis 760. The measurement structures comprise a first grating with a first pitch and a second grating with a second pitch. The intensity of the outgoing electromagnetic radiation (e.g., the electromagnetic signal measured at a detector) is plotted as a function of grayscale according to scale 706, in arbitrary units. The electromagnetic signal is plotted along an x-axis 702 (in arbitrary units of distance) and y-axis 704 (in arbitrary units of distance) for the first measurement structure oriented with periodic elements perpendicular to a line 710 and the second measurement structure with periodic elements perpendicular to a line 740. The graph 700 displays periodicity for both measurement structures along the x-axis 702, but does not display periodicity in a simple sinusoidal curve. For example, the first measurement structure displays a global maximum and two satellite local maxima inside a box 720 and the second measurement structure displays variable local maxima peak height in a box 730.

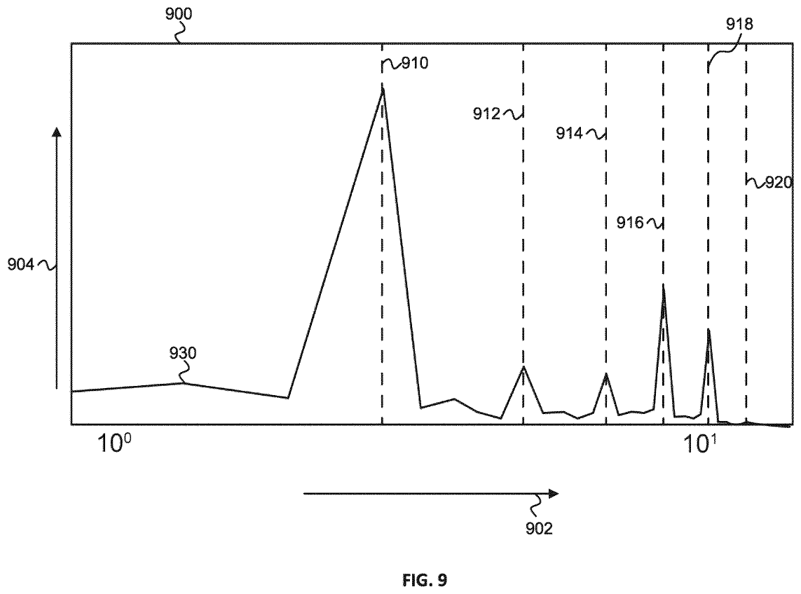

FIG. 8 depicts a graph of intensity of a Moiré interference pattern along a cross section in the direction x of FIG. 7. A graph 800 depicts the intensity along the line 710 of the graph 700 of FIG. 7. A line 810 represents measured intensity in arbitrary units of intensity along y-axis 804 as a function of distance along an x-axis 802 (in arbitrary units). The line 810 displays periodicity at several frequencies (e.g., at various pitches or wavelengths). A first period 812 is displayed by a repeating pattern of local maxima and minima in intensity. A second period 814 occurs between local maxima with varying intensities.

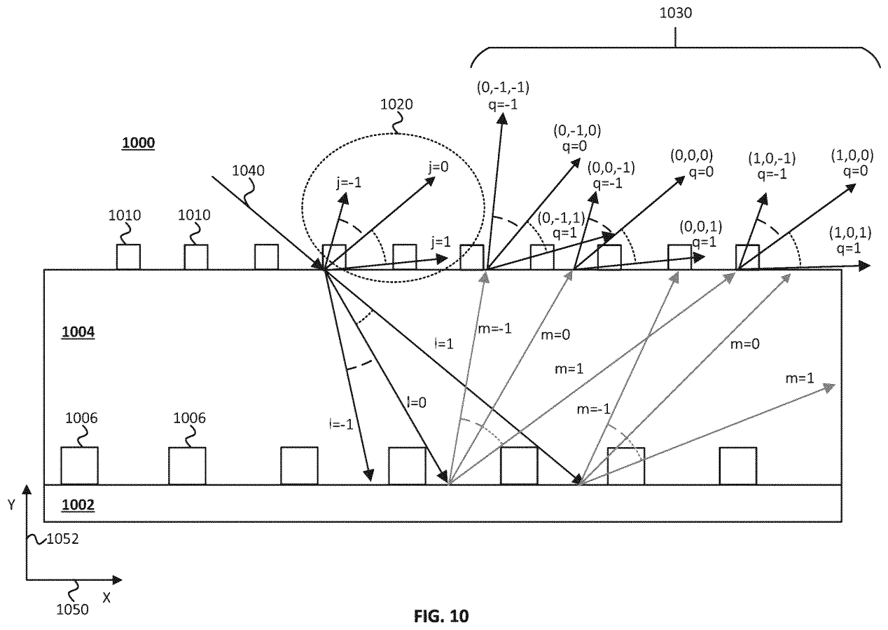

FIG. 9 depicts a graph of frequency components of the Moiré interference pattern of cross-sectional intensity of FIG. 8 as a function of frequency, according to an embodiment. A graph 900 depicts a frequency transform of the intensity shown in the graph 800 of FIG. 8. A line 930 represents amplitude (along y-axis 904 in arbitrary units) as a function of frequency (along x-axis 902). The frequency can be determined by using a Fourier transform or other frequency transform. The line 930 displays peaks at values marked by a line 910, which can correspond to a Moiré interference pattern component at a first frequency—which can be the Moiré pitch frequency; a line 912, which can correspond to a second Moiré interference pattern component; a line 914, which can correspond to a third Moiré interference pattern component; a line 916, which can correspond to a fourth Moiré interference pattern component; a line 918, which can correspond to a fifth Moiré interference pattern component; and a line 920, which can correspond to a sixth Moiré interference pattern component. The Moiré interference pattern components depicted are representative examples and can be instead located at different frequencies, have different intensities, and more or fewer Moiré interference pattern components may be present. For example, in the graph 900, the sixth Moiré interference pattern component has a relatively small amplitude. Additionally, peak widths for the various Moiré fringe may depend on amplitude or correspond to amplitude for various components or can be a function of the symmetry of the electromagnetic source or measurement structure or the degree of scattering.

A Moiré interference pattern can be comprised of multiple components of various frequencies or pitches. For example, a Moiré interference pattern can comprise a Moiré pitch or component with a period of the Moiré pitch, and can further comprise components with the period or pitch of each of the constituent pitches (e.g., the pitches of the gratings which produce the Moiré interference pattern). Additional components can arise due to interference and other effects with periods between the Moiré pitch and the constituent pitches. Additional components can also arise which have pitches or periods on the order of the least common multiple of the constituent pitches or on the order of a supercell.

The Moiré interference pattern component can correspond to a frequency related to its period or pitch. The Moiré interference pattern components can be determined based on a multiple of the Moiré pitch, for example using the relationship below.

$$Moire Interference Pattern Component Pitch = \frac{1}{n} \frac{{P}_{1} {P}_{2}}{\vert {P}_{1} - {P}_{2} \vert} \qquad ( 3 )$$

Where n can be an integer. In some cases, n can be a fraction or ration, such as 2/3 or 3/2. For an example measurement structure with grating pitches of 500 and 600 (in arbitrary units), the Moiré interference pattern can have strong components which occur at pitches of 3000 (again in arbitrary units) where 3000 is both the lowest common multiple and the Moiré pitch (as given by Equation 1). The Moiré interference pattern can further have strong components at the constituent pitches—e.g., at 500 and 600 (in arbitrary units). Additional components can occur at 1500, 1000, 750, etc. These pitches represent multiples of the Moiré frequency, which is the frequency which corresponds to the Moiré pitch.

Moiré interference patterns can be created by interference between semitransparent patterns. However, for a measurement structure comprising a first grating and a diffraction grating, diffraction as well as reflectance can generate Moiré interference patterns. A diffracted, refracted, reflected, or otherwise altered pattern (hereinafter “scattered”) can be generated from either the buried diffraction grating or the exposed diffraction grating. The intensity of outgoing electromagnetic radiation can be affected by the absorbance of the stack medium and other physical and electronic properties of the measurement structure. By accounting for scattered electromagnetic radiation (e.g., by inclusion of first order and higher diffraction wavepaths), weaker electromagnetic signals can be strengthened such that Moiré interference pattern components can be measured based on the electromagnetic signal. The Moiré interference patterns can therefore be measured as optical images (e.g., captured by lenses or cameras) or measured as diffraction-based signals (e.g., measured as diffracted or otherwise scattered electromagnetic signals).

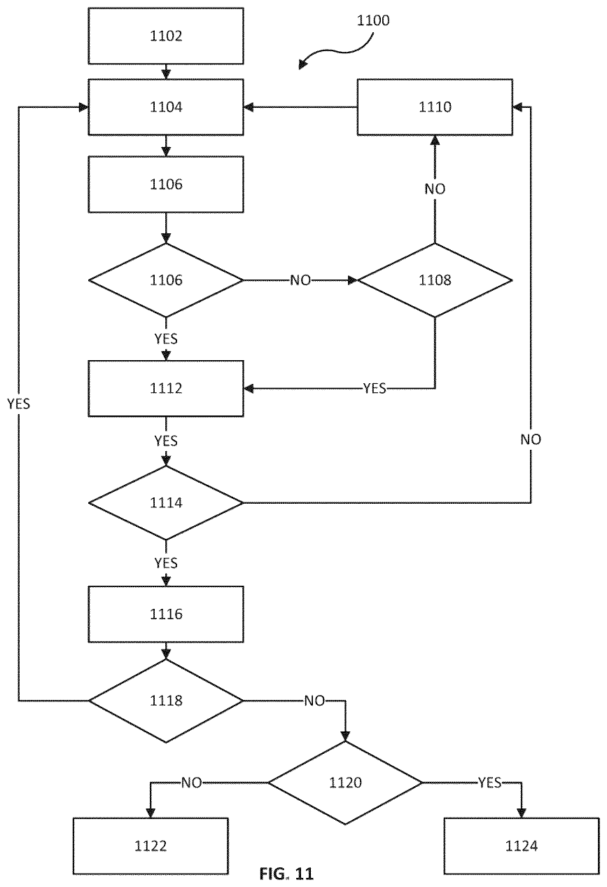

FIG. 10 depicts a schematic illustration of scattering in a measurement structure comprising a first grating with a first pitch and a second grating with a second pitch. The measurement structure 1000 comprises a substrate 1002, a first grating 1006, a stack medium 1004, and a second grating 1010. The substrate 1002 can be any appropriate substrate, as previously described in reference to FIG. 5. The stack medium 1004 can be any appropriate stack medium, as previously described. The first grating 1006 can be any appropriate grating with a first pitch and the second grating 1010 can be any appropriate grating with a second pitch, as previously described. The measurement structure is depicted with reference to an x-axis 1050 and a y-axis 1052.

The measurement structure 1000 may be subjected to incident electromagnetic radiation 1040 in order to measure one or more characteristics of the measurement structure 500. The incident electromagnetic radiation 1040 can be of a specific wavelength or phase, for example laser light, or can be of a range of wavelengths or phases including collimated light, white light, UV light, EUV light, etc. The incident electromagnetic radiation 1040 can approach the measurement structure 1000 obliquely, as shown, at a high angle to the substrate, at a low angle to the substrate, perpendicular to the substrate, etc. The incident electromagnetic radiation 1040 can be reflected, transmitted, diffracted or a combination thereof by the second grating 1010. For ease of description, photons (e.g., electromagnetic radiation quanta) which are diffracted, reflected, or otherwise returned from the second grating 1010 without interacting with the stack medium 1004 or the first grating 1006 will be identified by a wavepath with a value j. A j value of zero (0) corresponds to the zeroth order diffraction path (e.g., reflected photons), while a j value of ±n refers to a diffraction path of order±n. Within the oval 1020, the zeroth order and positive and negative first order diffraction paths are shown for electromagnetic radiation interacting with the second grating alone.

The incident electromagnetic radiation 1040 which enters the stack medium 1004 can be refracted, as a function of the index of refraction of the stack medium 1004 and the index of refraction of layers above the second grating 1010. The incident electromagnetic radiation 1040 which enters the stack medium 1004 can also be absorbed or otherwise dispersed.

The incident electromagnetic radiation 1040 which reaches the first grating 1006 can be reflected, transmitted, diffracted, or a combination thereof (e.g., scattered) by the first grating 1006. For ease of description, photons which are diffracted, reflected, or otherwise returned from the first grating 1006 (e.g., through the stack medium 1004) are identified by a wavepath with a vector value (l, m, q), where l represents the diffraction order of the transmitted, refracted, or combination thereof beam which passes through the second grating 1010, m represents the diffraction order of the reflected, diffracted, or combination thereof beam which returns from the first grating 1006, and q represents the diffraction order of the transmitted, refracted, or combination thereof beam which passes through the second grating 1010. This path represents a transmitted, reflected, transmitted path between the surface (or other direction from which the incident electromagnetic radiation 1040 approaches) and a detector. These paths correspond to those paths depicted under the parentheses 1030. Wavepaths can also occur which are involved in more reflections, fewer reflections, and higher or lower order diffractions. The wavepaths depicted here are illustrative only and should not be taken as representing all of the possible wavepaths. Moiré interference (e.g., interference which generates a Moiré interference pattern) can occur between any two wavepaths, as each wavepath represents a photon with a wavelength which travels a distance. The distance traveled depends on the geometry of the measurement structure 1000, the material and electrical properties of the stack medium 1004, the first grating 1006, the second grating 1010, etc. Diffraction (or other scattering) from the gratings can cause changes in Moiré interference patterns. The frequency and amplitude of Moiré interference patterns can depend on the first pitch, the second pitch, their separation, and material properties of the measurement structure 1000 (e.g., material properties of the stack).

Moiré interference patterns can be generated between a various wavepaths—and between Moiré interference patterns and additional physical patterns or patterns generated by physical elements. For incident electromagnetic radiation \vec{E₀} the outgoing electromagnetic radiation \vec{E_{ι}} can be measured as a function of the x direction using Equation 4, below:

$$\vec{{E}_{x}} = {\sum }_{i = - ∞}^{∞} \vec{{E}_{ι}} exp \{ {jk}_{i} x \} \qquad ( 4 )$$

where j represents the imaginary unit j²=−1, kᵢ is the ith wavenumber, and \vec{E_{ι}} is the amplitude coefficient of the outgoing electromagnetic radiation. The wavenumber is an allowed or quantum state of the measurement structure and can be described using Equation 5, below:

$${k}_{i} = {k}_{0} + 2 π \frac{i}{P} \qquad ( 5 )$$

where k₀ is the wavenumber of the incident electromagnetic radiation, i is an integer, and P is the lowest common multiple of the first pitch (e.g., P₁) and the second pitch (e.g., P₂). The intensity of the electromagnetic signal (e.g., the outgoing electromagnetic radiation as a function of the direction x) can then be given by a superposition of a set of frequency components defined in an algebraic operation between different kᵢ values, which can be approximated as a superposition of cosine waves, which can have a frequency or periodicity which depends on one or more wavenumbers. The intensity of the electromagnetic signal can instead be approximated using a superposition of sine wave, exponential functions (including imaginary exponential functions), etc., with appropriately chosen frequencies and phase shifts. Hereafter, a superposition of cosine waves is discussed but other periodic functions can be used.

The total Moiré interference pattern can therefore be represented by a superposition of cosine waves with frequencies represented by different wavenumbers. The amplitude of each cosine wave component depends strongly on stack properties (e.g., absorbance, thickness, bandgap, etc.). However, the frequency spectrum and phase shift with respect to overlay can be estimate from their constituent frequency contributions. Further the effect of overlay offset (or of another parameter of interest in the manufacturing process) on frequency and phase shift can also be determined before amplitude is determined (or even without amplitude determination).

Each of the cosine wave component can be at least estimated for multiple wavepaths. As higher order diffractions and multiple reflections generate wavepaths which are weaker in intensity, these terms may be substantially equal to zero. However, wavepaths of a first type—in which the diffraction occurs at the top diffraction grating (e.g., second diffraction grating)—and wavepaths of a second type—in which electromagnetic radiation is transmitted through the top diffraction grating, reflected or diffracted from the buried diffraction grating (e.g., first diffraction grating) and transmitted through the top diffraction grating—can produce significant contributions to Moiré interference patterns. Combinations of various of first type wavepaths and second type wavepaths, and second type wavepaths with other second type wavepaths, can be analyzed to determine spatial frequencies which contribute significantly to a Moiré interference pattern.

For example, the frequency distribution can be determined based on the analysis of the wavepaths which contribute to the wavenumbers. For the interaction between a first type wavepath and a second type wavepath, with reference to the notation of FIG. 10, the frequency of a cosine wave component resulting from the interaction of the two wavepaths can be expressed as Equation 6, below:

$${k}_{c} = 2 π ( \frac{l}{{P}_{1}} + \frac{m}{{P}_{2}} + \frac{q}{{P}_{1}} - \frac{j}{{P}_{1}} ) \qquad ( 6 )$$

where the frequency of the cosine wave component, which is related to a total wavenumber k_{c}, can be determined from the wavenumber for the various segments and diffractions of the two wavepaths. Similarly, for interactions between two second type wavepaths, the frequency of the cross term can be expressed as Equation 7, below:

$${k}_{c} = 2 π ( \frac{{l}_{2} - {l}_{1}}{{P}_{1}} + \frac{{m}_{2} - {m}_{1}}{{P}_{2}} + \frac{{q}_{2} - {q}_{1}}{{P}_{1}} ) \qquad ( 7 )$$

where the subscript 2 represents the wavenumbers and diffraction orders of a second second type wavepath and the subscript 1 represents the wavenumbers and diffraction orders of a first second type wavepath.

The frequency of the various cross terms can be determined by exploring the possible values (j, l, m, q) for both types of wavepaths and interactions between both types of wavepaths. Significant spatial frequencies can be determined based on a known P₁ and P₂ or based on variable representation of the first pitch and the second pitch (for example, a relationship between the first pitch and the second pitch).

Based on the diffraction orders, a relationship between overlay (or another parameter of interest in the manufacturing process) and Moiré phase shift can be determined for each cosine wave component. In some cases, the relationship varies with respect to beam paths—that is different beam paths can have different Moiré shifts (or overlay sensitivity) with respect to the same overlay offset. The difference in overlay sensitivity for the various wavepaths and their interference patterns can cause overlay offset errors—errors in the measured overlay offset for a known overlay offset or overlay set-get errors. Other parameters of interest can be measured based on their relationship to the Moiré phase shift for one or more cosine wave component. For example, thickness of one or more stack materials may be determined based on interactions between wavepaths—as the distance traveled between the first grating and the second grating is dependent on the thickness of the one or more stack materials and as the length of the wavepath can affect the phase of the scattered photons of the wavepath.

For a stable overlay sensitivity, a measure of overlay offset or another parameter of interest can be extracted from the Moiré interference pattern—either from a measured Moiré interference pattern comprising multiple components or by extracting one or more Moiré interference pattern components and determining a measure of overlay offset or another parameter of interest based on the extracted components. For example, we can write the intensity of a particular Moiré pattern as follows in Equations 8 and 9:

$${I}_{+ 1} ( x ) = 2 \vert {{E}_{C}}^{2} \vert cos ( {k}_{C} ( x + OVL ) + {φ}_{C +} ) \qquad ( 8 )$$

$${I}_{- 1} ( x ) = 2 \vert {{E}_{C}}^{2} \vert cos ( {k}_{C} ( x + OVL ) - {φ}_{C -} ) \qquad ( 9 )$$

where I₊₁(x) and I₋₁(x) represent the intensity as a function of x for the positive and negative diffraction branches. E_{C} is a constant related to the total electromagnetic intensity of the wavepaths which have interfered to generate the Moiré interference pattern component c and can represent the electromagnetic intensity of one or more wavepaths which generate the Moiré interference pattern component c—for example, E_{C} can be equal (including approximately equal or equal to within a constant factor) to E_{A}*E_{B} and have units of intensity or electromagnetic field strength squared. k_{c} is the total wavenumber of the wavepaths for the component c, and φ_{C+} and φ_{C-} represent phase shifts for the positive and negative image orders, respectively. The φ_{C+} and φ_{C-} phase shifts can include contributions from optical components—e.g., from the incident electromagnetic source, from optical components (lens, focus, collimator, etc.), from the detector, etc.

Because of the number of variables or unknowns and the number of equations, generally two sets of measurement structures with inverted pitches (i.e., the first pitch of the first structure is the second pitch of the second structure and vice versa) are used to identify overlay offset. Traditionally these two measurement structures or pads can be called the M pad (where the top pitch is larger than the buried pitch) and the W pad (where the buried pitch is larger than the top pitch), which is the case with cDBO (continuous diffraction-based overlay) marks which can be used to measure an overlay offset or another parameter of interest in the manufacturing process. The measurement structures can instead have different pitches (e.g., non-inverted pitches). By using Moiré interference pattern components at various pitches (or frequencies) for overlay offset extraction, a single measurement structure (e.g., pad) can be used instead of the traditional two pad configuration which can save area and therefore cost during fabrication of an electronic device. In an analog to conventional cDBO metrology, M and W can be used to represent different Moiré components obtained from a single pad, e.g., the two sets of equations generated from M^{th} Moiré frequency (or M paths) and W^{th} Moiré frequency (or W paths) respectively. Based on the Moiré frequency components, overlay offset can be measured using Equation 10, below:

$$OVL = \frac{1}{2} \frac{{S}^{M} {Φ}^{M} - {S}^{W} {Φ}^{W}}{{K}^{M} - {K}^{W}} \qquad ( 10 )$$

where S^{M}, S^{W}, K^{M}, and K^{W} are coefficients based on the M and W paths. Based on Equation 10, overlay offset and other overlay information can clearly be extracted from two different Moiré interference pattern components (or frequencies).

The use of multiple components of a Moiré interference pattern can provide improvements on current technology. For example, some measurement structures which contain a first grating and a second grating are used in optical metrology to measure overlay offset or other parameters of interest. The multi-grating structure can include gratings with frequencies visible to optical metrology tools—such as cameras, optical microscopes, etc. The grating sizes can therefore be larger than CD for the most advanced devices. Additionally, extraction of overlay offset or other parameters of interest from a multi-grating structure can require multiple multi-grating structures given the number of variables and equations which are solved.

In another example, a measurement structure can contain a first grating and a second grating which have different pitches and which function as diffraction gratings. The diffraction-based measurement structure can be used to generate a diffraction pattern, which can be a type of interference pattern. From a relationship between the diffraction pattern corresponding to the first grating and the diffraction pattern corresponding to the second grating, overlay offset and other parameters of interest can be measured. Diffraction-based measurement structures typically have grating periodicity on the order of the wavelength used to interrogate the structure—which can be smaller than optical wavelengths. However, diffraction-based measurement structures can suffer from deleterious electromagnetic effects. As wavelengths become smaller, such as would be used to interrogate devices with smaller CDs, the photon energy increases which can cause destructive interaction with the stack structure (e.g., resist breakdown, ionization damage, etc.). Additionally, diffraction-based measurements are based on detection of diffracted photons from buried layers. For highly absorbent stack materials (i.e., thick stack materials, narrow band gap materials, etc.), few photons are diffracted.

By using multiple components of a Moiré interference pattern for a multi-grating structure, the number of measurement structures required to deterministically identify an overlay offset or another parameter of interest can be reduced. The total number of equations which can be solved for the multi-grating measurement structure can be increased by the number of components of the Moiré interference pattern which are used (e.g., those which have a linear relationship with the overlay offset or parameter of interest over the range of wavelengths). Additionally, multiple types of scattered photons can be collected by the detector. This allows interrogation of buried gratings of layers for which pure diffraction measurements are insufficiently strong and therefore allows determination of overlay offset or other parameters of interest for absorbent stack materials. By identifying multiple components of a Moiré interference pattern, metrology (and, optionally, alignment) can be improved in accuracy. A single pad (e.g., a single multi-grating measurement structure), which can be used to determine overlay offset or another parameter of interest, also represents a geometrical space saving in a die which can increase the area of the die available for IC device fabrication and therefore increase the device density and profitability of the die.

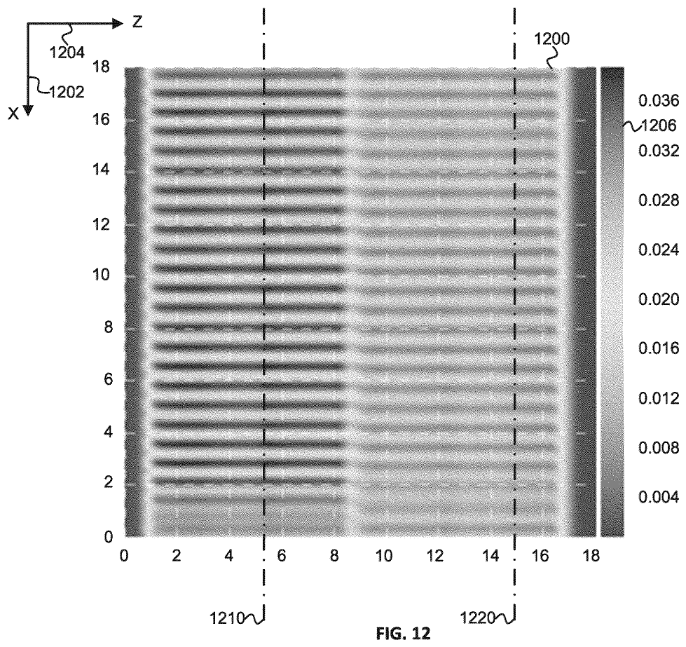

FIG. 11 illustrates an exemplary method 1100 for evaluation of a Moiré interference pattern for overlay offset measurement. Each of these operations is described in detail below. The operations of method 1100 presented below are intended to be illustrative. In some embodiments, method 1100 may be accomplished with one or more additional operations not described, and/or without one or more of the operations discussed. Additionally, the order in which the operations of method 1100 are illustrated in FIG. 11 and described below is not intended to be limiting. In some embodiments, one or more portions of method 1100 may be implemented (e.g., by simulation, modeling, etc.) in one or more processing devices (e.g., one or more processors). The one or more processing devices may include one or more devices executing some or all of the operations of method 1100 in response to instructions stored electronically on an electronic storage medium. The one or more processing devices may include one or more devices configured through hardware, firmware, and/or software to be specifically designed for execution of one or more of the operations of method 1100, for example.

At an operation 1102, stack information is obtained. The stack information can include information about the substrate, the first grating, the stack medium, the second grating and any other material dimensions and properties (e.g., material properties or electrical properties). The stack information can also include information about the incident electromagnetic radiation, such as wavelength, wavelength range, spot size, etc. The stack information can also include information about properties for measurement of the outgoing electromagnetic radiation (e.g., electromagnetic signal) including detectable wavelengths, detectable intensities, detectable angles, etc. The stack information can include information about the first grating and the second grating, including information about pitch, shape, physical dimensions, materials. The stack information can include a range of values for one or more parameter—for example a range for the pitch of the first grating or the second grating. The information about the first grating and the second grating can include lithographic, depositional, etchant, or other fabrication information, including fabrication limitations and fabrication thresholds. The stack information can include a critical dimension or geometry or overlay offset resolution threshold. The stack information can include design parameters which can be iteratively updated. The design parameters can include design parameters of the first diffraction grating and the second diffraction grating, including pitch.

At an operation 1104 a Moiré interference pattern component is selected for evaluation. The selected Moiré interference pattern component can be a Moiré interference pattern component with a period corresponding to the Moiré pitch or a Moiré interference pattern component with a smaller or larger pitch. The Moiré interference pattern components can be selected in order of pitch size or frequency from a range or series of Moiré interference pattern components. The Moiré interference pattern component at the Moiré pitch can optionally be omitted from the Moiré interference pattern components selected for evaluation. The Moiré interference pattern components can be limited to a range of Moiré interference pattern components (e.g., a range of pitch dimensions, frequencies, a number of multiples of a pitch, a number of multiples of a frequency, etc.). As an example Moiré interference pattern components can be limited to components with a period between the Moiré pitch and the smallest of the constituent pitches (e.g., the smallest of the top pitch and the buried pitch).

At an operation 1106, a sensitivity is determined for the selected Moiré interference pattern component based on the stack information. The sensitivity can be an overlay sensitivity and can be determined as previously described. Alternatively, the sensitivity can be a sensitivity with respect to another parameter of interest in the manufacturing process. The sensitivity can be determined based on pitch (e.g., the first pitch of the first grating and the second pitch of the second grating). The sensitivity can be determined based on pitch and one or more parameters of the stack information. The sensitivity can be determined based on an overlay offset for the first grating relative to the second grating or an overlay offset for the second grating relative to the first grating. The sensitivity can be determined as a function of one or more of the pitches. The sensitivity can be determined for a range or set of wavepaths which contribute to the selected Moiré interference pattern component, as previously described. The sensitivity can be determined for a wavelength of incident electromagnetic radiation or a range of wavelengths.

At an operation 1106, it is determined if the sensitivity for the selected Moiré interference pattern component is linear with respect to overlay offset or another parameter of interest. If linearity for the sensitivity if found, then the selected Moiré interference pattern component is conditionally accepted for overlay offset measurement or measurement of another parameter of interest. Linearity can encompass perfect linearity with respect to overlay offset or another parameter of interest for a wavelength or range of wavelengths of incident electromagnetic radiation. Linearity can also encompass a constant linear relationship or substantially constant fitting factor between sensitivity and overlay offset or another parameter of interest over a range of wavelengths. Linearity can also encompass substantially linear, linear to within a threshold, linear over a sub range of a range of wavelengths, etc. If it is determined that the overlay sensitivity for the selected Moiré interference pattern component is linear, flow continues to an operation 1112. If it is determined that the overlay sensitivity for the selected Moiré interference pattern component is not linear, flow continues to an operation 1108.

At the operation 1108, it is determined if the sensitivity for the selected Moiré interference pattern component is sufficiently linear. In some embodiments, it can be determined if the overlay meats a minimum linearity threshold or is otherwise sufficiently linear. For example, if one or more wavepath of the selected Moiré interference pattern component generates a nonlinear contribution, a linearity percentage, such as which percentage of wavepaths generate linear sensitivity versus which percentage of wavepaths generate nonlinear overlay sensitivity, or another measure can be determined. In some embodiments, the sensitivities which are determined can be grouped by the number of wavepaths which contribute to them. If one sensitivity is generated by a majority or a plurality of the wavepaths, the sensitivity can be conditionally marked or selected as linear for the selected Moiré order which can be conditionally accepted for measurement of the overlay offset. In some embodiments, if multiple sensitivities are generated by various wavepaths, or a comparable number of wavepaths are found for two or more sensitivities, the selected Moiré interference pattern component can be rejected. If it is determined that the sensitivity for the selected Moiré interference pattern component is not sufficiently linear, flow continues to an operation 1110. If it is determined that the sensitivity for the selected Moiré interference pattern component is sufficiently linear, flow continues to the operation 1112.

At the operation 1110, the selected Moiré interference pattern component can be rejected for measurement of the overlay offset or another parameter of interest. The rejection can be conditional or final. Data from the analysis of the selected Moiré interference pattern component can be stored for evaluation of the contribution of the selected Moiré interference pattern component to a measured Moiré interference pattern. The selected Moiré interference pattern component can be marked as rejected, including with information about the reason for the rejection, in a list or other data structure which can include all or a subset of all the Moiré interference pattern components of the measurement structure which have been or will be evaluated. After the selected Moiré interference pattern component is rejected, an additional Moiré interference pattern component can be selected for evaluation at the operation 1104.

At the operation 1112, the strength of the selected Moiré interference pattern component is determined. The strength of the selected Moiré interference pattern component can be determined based on a full or partial electromagnetic simulation for the measurement structure over a wavelength or range of wavelengths. The electromagnetic simulation can be based on a full reconstruction of the stack medium and other components of the measurement structure. The electromagnetic simulation can be based on some parameters of the stack information, which can be less than all parameters of the stack information. Alternatively, the electromagnetic simulation can be based on all or substantially all available parameters of the stack information.

A transform can then be used to extract the frequency components of the full or partial electromagnetic simulation. The strength of the selected Moiré interference pattern component can be determined based on the absolute peak intensity or a peak intensity value, which can be a pixel value, from the electromagnetic simulation. One or more constant term can be removed from the full or partial electromagnetic simulation. The strength of the selected Moiré interference pattern component can be determined based on peak intensity instead of on contrast or threshold. The strength of the selected Moiré interference pattern component can be determined as an intensity, an intensity above background, as an intensity above a minimum or threshold, as an intensity ratio, etc. The strength of the selected Moiré interference pattern component can be determined based on a pixel value, for example for an image produced by or based on an electromagnetic simulation. In some embodiments, the strength of one or more Moiré interference pattern components, which can include the selected Moiré interference pattern component, can be determined in one operation. This can include generation of a full or partial electromagnetic simulation and extraction of one or more Moiré interference pattern components by frequency transform, frequency reconstruction, etc. The strengths of the one or more Moiré interference pattern components can be evaluated as relative strengths, as absolute strengths, as differences in strengths, etc. The strengths of the one or more Moiré interference pattern components can be compared to a Moiré interference pattern component strength for the Moiré pitch, an incident electromagnetic radiation strength, a total electromagnetic signal strength, etc. The strengths of the one or more Moiré interference pattern components can also be determined based on a resolution or estimated resolution capabilities of any detector used to measure the outgoing electromagnetic radiation. A full or partial electromagnetic simulation can be performed at a first operation, such as the operation 1112, where the strengths of a set of one or more Moiré interference pattern components are stored. At subsequent operations, the strengths of a selected Moiré interference pattern component can be recalled from storage in order for the selected Moiré order to be analyzed.

At an operation 1114, it is determined if the strength of the selected Moiré interference pattern component is sufficiently strong. The strength of the selected Moiré interference pattern component can be compared to a threshold, to the strength of one or more other Moiré order strengths, including to a zeroth order or incident electromagnetic radiation strength. The strength of the selected Moiré interference pattern component can be compared to a threshold in relative terms (e.g., as a percentage or ratio) or can be compared to a threshold in absolute terms (e.g., in a pixel value or absolute intensity).

Optionally, for a selected Moiré interference pattern component with multiple overlay sensitivities (e.g., a Moiré interference pattern component which was conditionally accepted for overlay offset measurement based on the operation 1108 or a similar operation) Moiré interference pattern component strength can be evaluated for the different sensitivities previously determined (such a first overlay sensitivity, a second overlay sensitivity, etc.) and compared. The relative strength of the multiple sensitivities can be used to evaluate the linearity of the selected Moiré interference pattern component. For example, for a selected Moiré interference pattern component with a first sensitivity which is determined to correspond to a first strength and a second sensitivity which is determined to a second strength, the selected Moiré interference pattern component can be accepted for overlay offset measurement or measurement of another parameter of interest if the strengths are unequal, such that one strength dominates the contribution of the selected Moiré interference pattern component. Alternatively, if the strengths are substantially similar, the selected Moiré interference pattern component can be rejected for overlay offset measurement.

Determination of the strength of the selected Moiré interference pattern component (or of multiple Moiré interference pattern components) can include determination of the strength of the selected Moiré interference pattern component for one or more value of overlay offset or another parameter of interest. The electromagnetic simulation can include an electromagnetic simulation for multiple values of the overlay offset (e.g., an overlay offset of zero, a small positive overlay offset, a small negative overlay offset, etc.) or another parameter of interest. The electromagnetic simulation can include determination of the strength of the selected Moiré interference pattern component, and optionally determination of a response of the selected Moiré interference pattern component, for several overlay offsets (or other parameters of interest). The electromagnetic simulation can include evaluation of the frequency, intensity, relative strength, etc. for the selected Moiré interference pattern component for a wavelength or range of wavelengths.

If it is determined that the strength of the selected Moiré interference pattern component is sufficiently strong, flow continues to an operation 1116. If it is determined that the strength of the selected Moiré interference pattern component is not sufficiently strong, flow continues to an operation 1110.

At the operation 1116, the selected Moiré interference pattern component can be approved for overlay offset measurement or measurement of another parameter of interest in the manufacturing process. A marker can be added to the approved Moiré interference pattern component, such that one or more approved Moiré interference pattern components can be collated and compared. Alternatively, an approved Moiré interference pattern component can be stored, including together with its electronic simulation components and strength simulation components. The approved Moiré interference pattern component can be further modeled or simulated.

At an operation 1118, it is determined if there are further Moiré interference pattern component to be evaluated or to be selected to be evaluated. The Moiré interference pattern components which have been evaluated, which have been accepted (including conditionally), which have been rejected (including conditionally), etc. can be compared to a set of Moiré interference pattern components to be evaluated. If it is determined that further Moiré interference pattern components remain to be evaluated, flow continues to the operation 1104 where another Moiré interference patter component is selected. If it is determined that no further Moiré interference pattern components remain to be evaluated, flow continues to an operation 1120. In some embodiments, it can be determined that no further Moiré interference pattern components remain to be evaluated if a sufficient number of Moiré interference pattern components have been accepted for overlay offset measurement or measurement of another parameter of interest. The number of accepted Moiré interference pattern components which would terminate the evaluation of other Moiré interference pattern components can be set by a threshold. The threshold can be a number of Moiré interference pattern components which can produce an overlay offset error or an order of magnitude for an overlay offset error or another accuracy or error threshold. The threshold can be a number of Moiré interference pattern components which allows for use of a single measurement structure (e.g., instead of dual M and W measurement structures) for measurement of overlay offset or another parameter of interest. The threshold can be an accepted Moiré interference pattern component at the Moiré pitch and a threshold number of additional Moiré interference pattern components for use in measurement of overlay offset or another parameter of interest. The threshold can be a number of Moiré interference pattern components which are not the Moiré interference pattern component at the Moiré pitch.

At the operation 1120, it is determined if the accepted Moiré interference pattern components include Moiré interference pattern components which are not the Moiré interference pattern component at the Moiré pitch. If the accepted Moiré interference pattern components do not include Moiré interference pattern components which periods smaller or larger than the Moiré pitch (e.g., the accepted Moiré interference pattern components only include a Moiré interference pattern component at the Moiré pitch), then the Moiré interference pattern component at the Moiré pitch can be selected for overlay offset measurement (or measurement of another parameter of interest) at an operation 1122. If the accepted Moiré interference pattern components include multiple Moiré interference pattern components, then the Moiré interference pattern components can be accepted for overlay offset measurement at an operation 1124. Alternatively, if no Moiré interference pattern components are accepted, the stack information can be adjusted and Moiré interference pattern components of the adjusted measurement structure can be evaluated. For example, the pitch of the first grating can be adjusted, the pitch of the second grating can be adjusted, the wavelength of the incident electromagnetic radiation can be adjusted, etc.

As described above, method 1100 (and/or the other methods and systems described herein) is configured to evaluate a Moiré interference pattern and its components for overlay offset measurement or measurement of another parameter of interest.

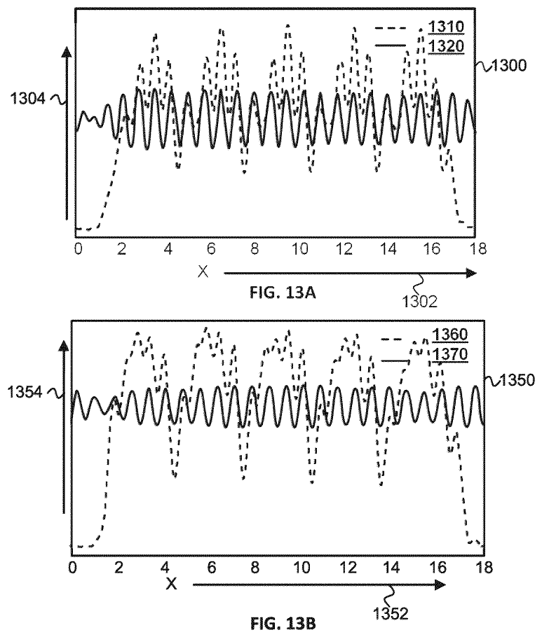

FIG. 12 depicts a graph of intensity of a Moiré interference pattern component in the x-y plane for a measurement structure. A graph 1200 depicts an example Moiré interference pattern for an extracted Moiré interference pattern component at one fourth of the Moiré pitch for a measurement structure with a first grating with a first pitch and a second grading with a second pitch. The intensity of the outgoing electromagnetic radiation (e.g., the electromagnetic signal) is plotted as a function of grayscale according to scale 1206, in arbitrary units. The electromagnetic signal is plotted along an x-axis 1202 (in arbitrary units of distance) and y-axis 1204 (in arbitrary units of distance) for a first measurement structure oriented with periodic elements perpendicular to a line 1210 and a second measurement structure with periodic elements perpendicular to a line 1220. The graph 1200 displays periodicity for both measurement structures along the x-axis 1202 where the periodicity is sinusoidal.

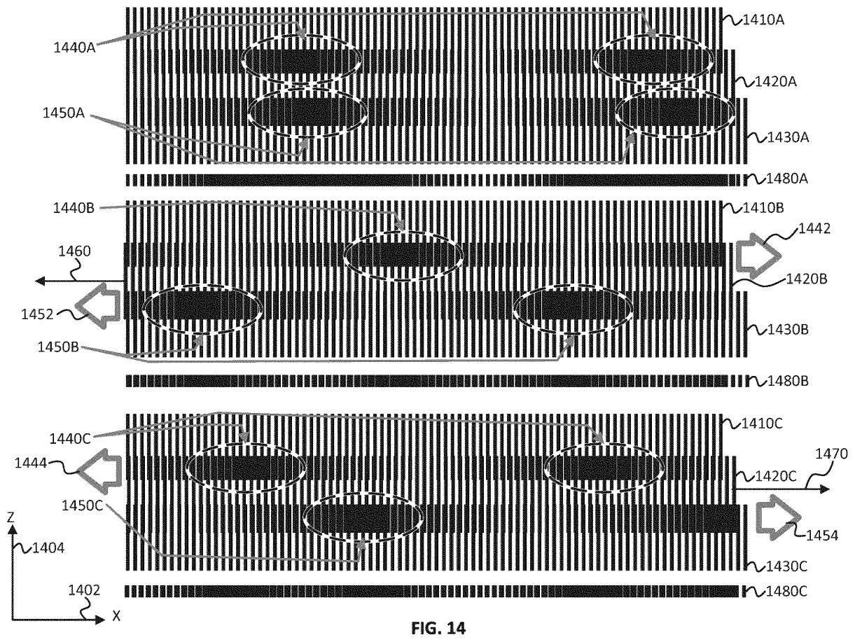

FIGS. 13A and 13B depicts graphs of intensity for Moiré interference patterns and extracted Moiré interference pattern components along cross sections in the direction x of FIG. 12, according to an embodiment.

FIG. 13A depicts a graph of intensity of a Moiré interference pattern and an extracted Moiré interference pattern component along a cross section in the direction x of FIG. 12. A graph 1300 depicts the intensity along the line 1210 of the graph 1200 of FIG. 12. A line 1310 represents measured intensity in arbitrary units of intensity along y-axis 1304 as a function of distance along an x-axis 1302 (in arbitrary units). The line 1310 displays periodicity at several frequencies. A line 1320 represents intensity in arbitrary units for the extracted Moiré interference pattern component of the measured intensity. The line 1320 exhibits sinusoidal periodicity at a frequency equal to four times the Moiré pitch frequency.

FIG. 13B depicts a graph of intensity of a Moiré interference pattern and an extracted Moiré interference pattern component along a cross section in the direction x of FIG. 12. A graph 1350 depicts the intensity along the line 1220 of the graph 1200 of FIG. 12. A line 1360 represents measured intensity in arbitrary units of intensity along y-axis 1354 as a function of distance along an x-axis 1352 (in arbitrary units). The line 1360 displays periodicity at several frequencies. A line 1370 represents intensity in arbitrary units for the extracted Moiré interference pattern component of the measured intensity. The line 1370 exhibits sinusoidal periodicity at a frequency equal to four times the Moiré pitch frequency.

In addition to a measurement structure comprising a first grating at a first pitch and a second grating at a second pitch, measurement structures including three of more pitches can generate Moiré interference patterns and can be used to measure overlay offset and other parameters of interest in the manufacturing process.

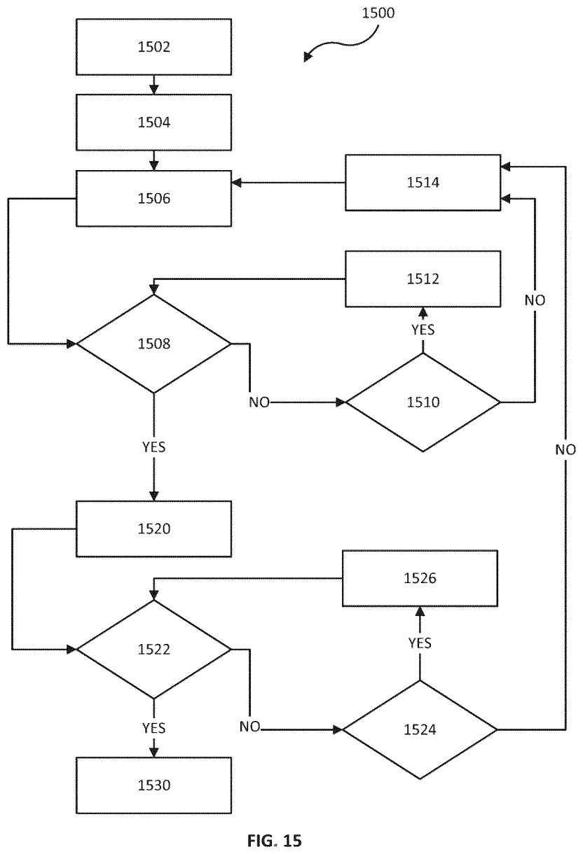

FIG. 14 illustrates an interference pattern for an example measurement structure comprising a first pitch, a second pitch, and a third pitch. The measurement structure is depicted as a set of three pitches (e.g., first pitch 1410A-1410C, second pitch 1420A-1420C, and third pitch 1430A-1430C), with various offsets (e.g., a zero offset in an x-direction 1402 for the first pitch 1410A, the second pitch 1420A, and the third pitch 1430A; a negative offset 1460 in the x-direction 1402 for the second pitch 1420B relative to the first pitch 1410B and the third pitch 1430B; and a positive offset 1470 in the x-direction 1402 for the second pitch 1420C relative to the first pitch 1410C and the third pitch 1430C).

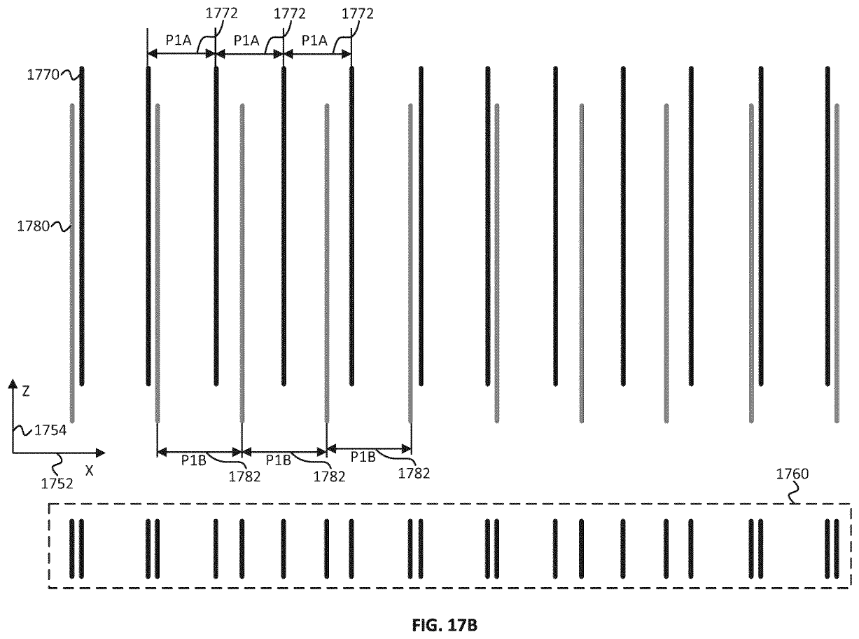

The first pitch 1410A-1410C, the second pitch 1420A-1420C, and the third pitch 1430A-1430C are depicted as separate gratings with overlapping regions in a z-direction 1404 for illustrative purposes. The first pitch 1410A-1410C, the second pitch 1420A-14020C, and the third pitch 1430A-1430C can instead substantially or completely overlap. Additionally, multiple pitches can be combined in one or more gratings, where the measurement structure can comprise a first grating in a first layer and a second grating in a second layer. A grating which comprises multiple pitches can be referred to as a composite grating, as it is composed of two or more pitches. For example, the first pitch 1410A-1410C and the third pitch 1430A-1430C can together comprise a first grating (e.g., a composite grating), while the second pitch 1420A-1420C can comprise a second grating. Likewise, a first grating can be comprised of any two pitches while the second grating is comprised of another of the pitches. A composite grating can be a buried grating or a top grating. In some examples, both the first grating and the second grating can be composite gratings. Various arrangements of composite gratings will be further discussed in relation to FIGS. 17A-17B, 18, 19, 20, 21, and 22. In the example as depicted, the first pitch 1410A-1410C is smaller than the second pitch 1420A-1420C, which is smaller than the third pitch 1430A-1430C. The relationship between the pitches can instead be different. Further, each of the pitches can vary or itself be a composite pitch.

Each of the pitches can generate an interference pattern when combined with another pitch. In an example, the first pitch 1410A-1410C and the third pitch 1430A-1430C can correspond to a first grating in a first layer while the second pitch 1420A-1420C can correspond to a second grating in a second layer. In this example, the first pitch 1410A-1410C and the third pitch 1430A-1430C have a substantially fixed relationship to one another, while the relationships between the first pitch 1410A-1410C and the second pitch 1420A-1420C and between the third pitch 1430A-1430C and the second pitch 1420A-1420C vary based as the second grating in the second layer shifts relative to the first grating in the first layer.

A representation of the Moiré interference pattern (e.g., the total interference pattern) caused by overlapping of the three pitches is depicted for the zero offset as pattern 1480A, for the negative offset 1460 as the pattern 1480B, and for the positive offset 1470 as the pattern 1480C. The patterns 1480A-1480C are compressed in the z-direction 1404 relative to the first pitch 1410A-1410C, the second pitch 1420A-1420C, and the third pitch 1430A-1430C as depicted. The size and separation of the elements of the pitches are chosen for ease of illustration and can instead by other sizes, separations, orientations, etc.

For the zero offset in an x-direction 1402 for the first pitch 1410A, the second pitch 1420A, and the third pitch 1430A, a first Moiré interference pattern is generated between the first pitch 1410A and the second pitch 1420A and a second Moiré interference pattern is generated between the third pitch 1430A and the second pitch 1420A. The local maxima of the first interference pattern are indicated by ovals 1440A. The local maxima of the second interference pattern are indicated by ovals 1450A.

For the negative offset 1460 in the x-direction 1402 for the second pitch 1420B relative to the first pitch 1410B and the third pitch 1430B, a first Moiré interference pattern is generated between the first pitch 1410B and the second pitch 1420B and a second Moiré interference pattern is generated between the third pitch 1430B and the second pitch 1420B. The local maxima of the first interference pattern are indicated by an oval 1440B. The local maxima of the first interference pattern are separated by substantially the same distance as the local maxima of the first interference pattern for the zero offset; however, the locations of the local maxima of the oval 1440B are shifted with respect to the local maxima of the ovals 1440A in the positive x-direction 1402, as indicated by an arrow 1442. The local maxima of the second interference pattern are indicated by ovals 1450B. The local maxima of the second interference pattern are separated by substantially the same distance as the local maxima of the second interference pattern for the zero offset; however, the locations of the local maxima of the ovals 1450B are shifted with respect to the local maxima of the ovals 1450A in the negative x-direction 1402, as indicated by an arrow 1452. The shift between the local maxima of the ovals 1440A, 1450A of the zero offset example and the local maxima of the ovals 1440B, 1450B of the negative offset 1460 example can be considered a phase shift in the Moiré interference pattern. In some cases, a shift in separation between the local maxima of the ovals 1440B, 1450B relative to the local maxima of the ovals 1440A, 1450A can also be present—e.g., a change in Moiré interference pattern frequency. For example, a change in focus, such as caused by a change in thickness of a layer of the measurement structure, can cause a change in the size of a pitch or pitch elements which can be reflected in a change in Moiré interference pattern frequency. Likewise, local minima and other features of the Moiré interference patterns can exhibit similar shifts in phase and frequency.

The negative offset 1460 can be any offset amount and can include offset in more than one direction (e.g., along more than one axis). The magnitude of the shifts of the local maxima of the first interference pattern and the second interference pattern can depend on the magnitude and direction of the offset amount between the pitches. The negative offset 1460 also causes a change in the pattern 1480B relative to the pattern 1480A, where the pattern 1480B is a composite of the first interference pattern and the second interference pattern. The pattern 1480B can be decomposed (e.g., through a frequency transform such as a fast Fourier transform (FFT), through superposition, etc.) into frequency components in order to reconstruct the first interference pattern and the second interference pattern in order to determine phase and frequency shift of each pattern.

For the positive offset 1470 in the x-direction 1402 for the second pitch 1420C relative to the first pitch 1410C and the third pitch 1430C, a first Moiré interference pattern is generated between the first pitch 1410C and the second pitch 1420C and a second Moiré interference pattern is generated between the third pitch 1430C and the second pitch 1420C. The local maxima of the first interference pattern are indicated by ovals 1440C. The local maxima of the first interference pattern are separated by substantially the same distance as the local maxima of the first interference pattern for the zero offset; however, the locations of the local maxima of the ovals 1440C are shifted with respect to the local maxima of the ovals 1440A in the negative x-direction 1402, as indicated by an arrow 1444.

The local maxima of the second interference pattern are indicated by an oval 1450C. The local maxima of the second interference pattern are separated by substantially the same distance as the local maxima of the second interference pattern for the zero offset; however, the locations of the local maxima of the ovals 1450C are shifted with respect to the local maxima of the ovals 1450A in the positive x-direction 1402, as indicated by an arrow 1454. The shift between the local maxima of the ovals 1440A, 1450A of the zero offset example and the local maxima of the ovals 1440C, 1450C of the positive offset 1470 example can be considered a phase shift in the Moiré interference pattern. As previously discussed, a change in Moiré interference pattern frequency can also be present. Local minima and other features of the Moiré interference patterns can exhibit shifts in phase and frequency similar to those exhibited by the local maxima of the ovals 1440C, 1450C described above.

The positive offset 1470 can be any offset amount and can include offset in more than one direction (e.g., along more than one axis). The magnitude of the shifts of the local maxima of the first interference pattern and the second interference pattern can depend on the magnitude and direction of the offset amount between the pitches. For example, the direction of the shifts of local maxima of the ovals 1440B, 1450B relative to the local maxima of the ovals 1440A, 1450A of the zero offset example are opposite the direction of the shifts of the local maxima of the ovals 1440C, 1450C relative to the local maxima of the ovals 1440A, 1450A of the zero offset example. For an interference pattern comprises of three pitches, the shifts can also be in the same direction, can be of the same magnitude, or can be of different magnitudes. The magnitude and direction of the shifts in the interference pattern with respect to offset of at least one pitch can also vary as a function of wavelength—e.g., can depend on the wavelength of the electromagnetic radiation used to interrogate the measurement structure.

The positive offset 1470 also causes a change in the pattern 1480C relative to the pattern 1480A, where the pattern 1480C is a composite of the first interference pattern and the second interference pattern. The pattern 1480C can be decomposed into frequency components in order to reconstruct the first interference pattern and the second interference pattern or to otherwise determine phase and frequency shift.

The phase (and optionally, frequency) shift of the first interference pattern and the second interference pattern relative to the zero offset patterns can be used to measure a parameter of interest in the manufacturing process. The first interference pattern and the second interference pattern can be used to measure a parameter of interest using a single pad geometry. The relative shifts of the first interference pattern and the second interference pattern can be used determine a center or other zero point for the Moiré interference pattern. Additionally, the interference pattern can be centrosymmetric eliminating the need for multiple measurement pads to determine symmetry and/or center of the measurement structure. A single pad can be more accurate—as a multi-grating measurement structure experiences less process variation than multiple multi-grating measurement structures. A single pad can also reduce wafer space used for measurement structures and therefore increase yield and profit for electronic devices. The first interference pattern and the second interference pattern can be used to calculate overlay as previously described for the multiple Moiré interference pattern components (such as by using Equation 10).

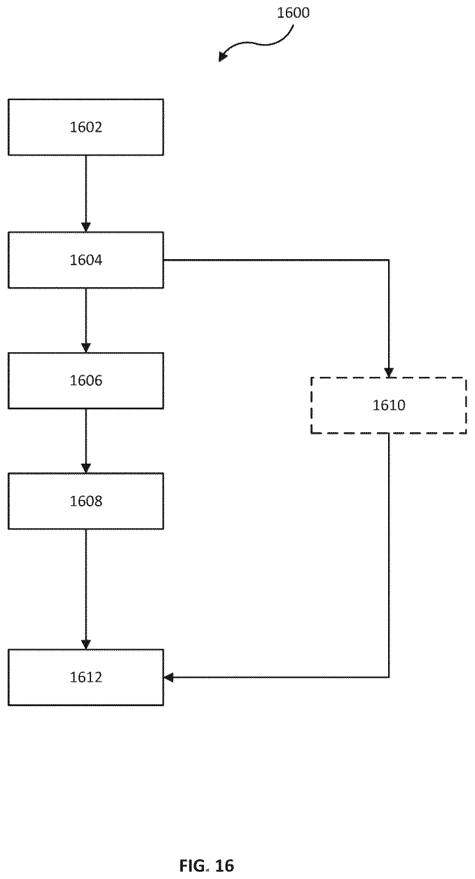

FIG. 15 illustrates an exemplary method 1500 for generation of a measurement structure for measurement of a parameter of interest in a manufacturing process based on multiple Moiré interference pattern components. Each of these operations is described in detail below. The operations of method 1500 presented below are intended to be illustrative. In some embodiments, method 1500 may be accomplished with one or more additional operations not described, and/or without one or more of the operations discussed. Additionally, the order in which the operations of method 1500 are illustrated in FIG. 15 and described below is not intended to be limiting. In some embodiments, one or more portions of method 1500 may be implemented (e.g., by simulation, modeling, etc.) in one or more processing devices (e.g., one or more processors). The one or more processing devices may include one or more devices executing some or all of the operations of method 1500 in response to instructions stored electronically on an electronic storage medium. The one or more processing devices may include one or more devices configured through hardware, firmware, and/or software to be specifically designed for execution of one or more of the operations of method 1500, for example.

At an operation 1502, stack information is obtained. The stack information can be obtained according to methods previously described in reference to the operation 1102.

At an operation 1504, a first grating with a first pitch and a second grating with a second pitch are selected for evaluation. The first grating can be a composite grating, wherein the first pitch comprises a third pitch and a fourth pitch. The second grating can be a composite grating, wherein the second pitch comprises a fifth pitch and a sixth pitch. The first grating can be a buried grating and the second grating can be a top grating. The second grating can be a buried grating and the first grating can be a top grating. The first pitch and the second pitch can be selected based on stack information, including thickness, absorbance, etc. The first pitch and the second pitch can be selected based on design limitations from the stack information. The first pitch and the second pitch can be selected based on electromagnetic requirements—such as wavelength ranges for the electromagnetic source and detector. The first pitch and the second pitch can be selected based on critical dimensions of one or more feature in the stack information. In some cases, an additional grating with one or more additional pitches can also be selected.

At an operation 1506, a first Moiré interference pattern component is selected for evaluation. The first Moiré interference pattern component can be a Moiré interference pattern component for the first pitch of the first grating and the second pitch of the second grating. Additionally, for one or more composite grating, the first Moiré interference pattern component can be a Moiré interference pattern component for a pitch composing the first pitch of the first grating and a pitch comping the second pitch of the second grating. For a specific example, the first Moiré interference pattern component could be a Moiré interference pattern component for a third pitch, wherein the first grating is a composite grating with a third pitch and a fourth pitch, and a second pitch of the second grating, wherein the second grating is not a composite grating. The first Moiré interference pattern component can be further selected as previously described in relation to the operation 1104.

At an operation 1508, it is determined if the selected first Moiré interference pattern component is acceptable for measurement of the parameter of interest. The determination that the selected Moiré interference pattern component is acceptable for measurement of the parameter of interest can be performed as previously described in relation to the operations 1106-1116 or any other appropriate method. The first Moiré interference pattern can be evaluated based on linearity, wavelength range, strength, etc. If the selected first Moiré interference pattern is acceptable for measurement of the parameter of interest, flow continues to an operation 1520. If the selected first Moiré interference pattern is not acceptable for measurement of the parameter of interest, flow continues to an operation 1510.

At the operation 1510, it is determined if another first Moiré interference pattern can be selected for the first grating with the first pitch and the second grating with the second pitch. For example, a component of the first Moiré interference pattern can be selected, where the component can be a component of the first Moiré interference pattern at another frequency. In a specific example, if the Moiré pitch of the first Moiré interference pattern is X, a component of the first Moiré interference pattern at a pitch of X*m/n can be selected for evaluation where m and n are integers. If another first Moiré interference pattern or component of the first Moiré interference pattern can be selected, flow continues to an operation 1512. If another first Moiré interference pattern or component of the first Moiré interference pattern cannot be selected, flow continues to an operation 1514.

At the operation 1512, another first Moiré interference pattern or component of the first Moiré interference pattern is selected for evaluation. The selected first Moiré interference pattern or component of the first Moiré interference pattern is then evaluated at the operation 1508.

At the operation 1514, either the first pitch, the second pitch, or both are adjusted. Adjusting the first pitch can comprise adjusting a third pitch, a fourth pitch, or both, where the first pitch is a composite pitch comprised of the third pitch and the fourth pitch. Likewise, adjusting the second pitch can comprise adjusting a fifth pitch, a sixth pitch, or both, where the second pitch is a composite pitch comprised of the fifth pitch and the sixth pitch. Adjusting at least one of the pitches can comprise adding an additional pitch. For example, adjusting the first pitch can comprise adding a third pitch to the first pitch such that the first grating becomes a composite pitch. Adjusting at least one of the pitches can be based on the stack information. The first pitch can be adjusted, the second pitch can be adjusted, or both pitches can be adjusted. A first Moiré interference pattern component for the at least one adjusted pitch is selected for evaluation at the operation 1506.

At the operation 1520, a second Moiré interference pattern is selected for evaluation. The second Moiré interference pattern can be different from the first Moiré interference pattern. The second Moiré interference pattern component can be a Moiré interference pattern component for the first pitch of the first grating and the second pitch of the second grating. Additionally, for one or more composite grating, the second Moiré interference pattern component can be a Moiré interference pattern component for a pitch composing the first pitch of the first grating and a pitch comping the second pitch of the second grating. For a specific example, the second Moiré interference pattern component could be a Moiré interference pattern component for a fourth pitch, wherein the first grating is a composite grating with a third pitch and a fourth pitch, and a second pitch of the second grating, wherein the second grating is not a composite grating. The second Moiré interference pattern component can be further selected as previously described in relation to the operations 1104, 1506.

At an operation 1522, it is determined if the selected second Moiré interference pattern component is acceptable for measurement of the parameter of interest. The determination that the selected Moiré interference pattern component is acceptable for measurement of the parameter of interest can be performed as previously described in relation to the operations 1106-1116 and 1508 or any other appropriate method. The second Moiré interference pattern can be evaluated based on linearity, wavelength range, strength, etc. If the selected second Moiré interference pattern is acceptable for measurement of the parameter of interest, flow continues to an operation 1530. If the selected first Moiré interference pattern is not acceptable for measurement of the parameter of interest, flow continues to an operation 1524.

At the operation 1524, it is determined if another second Moiré interference pattern can be selected for the first grating with the first pitch and the second grating with the second pitch. For example, a component of the second Moiré interference pattern can be selected, where the component can be a component of the second Moiré interference pattern at another frequency. In a specific example, if the Moiré pitch of the first Moiré interference pattern is X, a component of the second Moiré interference pattern at a pitch of X*n can be selected for evaluation. If another second Moiré interference pattern or component of the second Moiré interference pattern can be selected, flow continues to an operation 1526. If another second Moiré interference pattern or component of the second Moiré interference pattern cannot be selected, flow continues to the operation 1514.

At the operation 1526, another second Moiré interference pattern or component of the second Moiré interference pattern is selected for evaluation. The selected second Moiré interference pattern or component of the second Moiré interference pattern is then evaluate at the operation 1522.

At the operation 1530, a measurement structure is generated based on the first Moiré interference pattern and the second Moiré interference pattern for the first pitch of the first grating and the second pitch of the second grating. Additional evaluation can be performed. The measurement structure can be generated on a fabricated device. Alternatively, one or more photolithography step, etch step, deposition step, etc. can be performed to generate the measurement structure. One or more photolithography masks can be designed, generated, or both based on the measurement structure.

As described above, method 1500 (and/or the other methods and systems described herein) is configured to generate a measurement structure for a parameter of interest in a manufacturing process based on multiple Moiré interference pattern components.

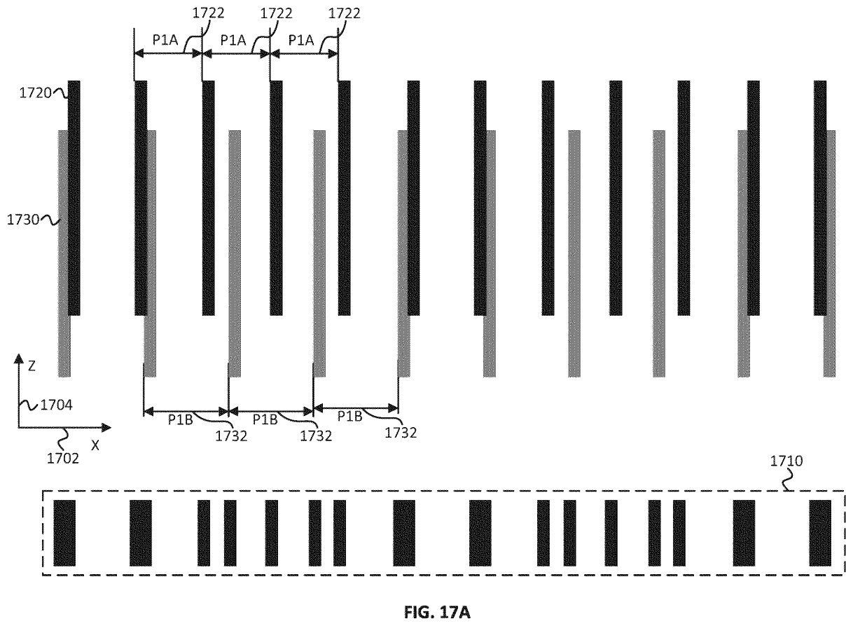

FIG. 16 illustrates an exemplary method 1600 for determination of a parameter of interest in a manufacturing process based on multiple Moiré interference pattern components. Each of these operations is described in detail below. The operations of method 1600 presented below are intended to be illustrative. In some embodiments, method 1600 may be accomplished with one or more additional operations not described, and/or without one or more of the operations discussed.

Additionally, the order in which the operations of method 1600 are illustrated in FIG. 16 and described below is not intended to be limiting. In some embodiments, one or more portions of method 1600 may be implemented (e.g., by simulation, modeling, etc.) in one or more processing devices (e.g., one or more processors). The one or more processing devices may include one or more devices executing some or all of the operations of method 1600 in response to instructions stored electronically on an electronic storage medium. The one or more processing devices may include one or more devices configured through hardware, firmware, and/or software to be specifically designed for execution of one or more of the operations of method 1600, for example.

At an operation 1602, an interference pattern is obtained for a measurement structure. The interference pattern can be obtained by a detector. The interference pattern can be a Moiré interference pattern or be composed of one or more Moiré interference patterns. The interference pattern can be generated by scattered electromagnetic radiation from the measurement structure. The interference pattern can be obtained from data storage. The interference pattern can be a synthetic interference pattern. The interference pattern can undergo image processing-including one or more frequency transform, sharpening, filtering, etc. The interference pattern can be obtained for a range of wavelengths. The interference pattern can be obtained as a still image (e.g., a photograph or analog of a photograph) or as a time-series of images (e.g., a video or analog of a video). The interference pattern can comprise one or more types of intensity information, phase information, etc.

At an operation 1604, frequency components of the interference pattern are identified. The frequency components of the interference pattern can be determined by a frequency transform, such as an FFT, by superposition, or by any other appropriate method of frequency determination. The frequency components of the interference pattern can be identified in both the frequency and space domain, where the interference pattern can be reconstructed or otherwise aligned with its frequency components. One or more components of the interference patterns are selected. The components of the interference pattern can be themselves Moiré interference patterns or components of Moiré interference patterns. The components can have a frequency and phase.

At an operation 1606, a phase shift is determined for a first component of the interference pattern. The phase shift can be determined based on a model of the measurement structure for a specific value of the parameter of interest (e.g., for a zero offset value). The phase shift can be determined based on an arbitrary zero or center point for the interference pattern. The phase shift can be determined both phase, frequency, amplitude, or a combination thereof of the first component of the interference pattern. The phase shift for the first component can be determined as both a direction and a magnitude.

At an operation 1608, a phase shift is determined for a second component of the interference pattern. The phase shift can be determined based on a model of the measurement structure for a specific value of the parameter of interest (e.g., for a zero offset value). The phase shift can be determined based on an arbitrary zero or center point for the interference pattern. The phase shift can be determined both phase, frequency, amplitude, or a combination thereof of the second component of the interference pattern. The phase shift for the second component can be determined as both a direction and a magnitude. The phase shift for the second component can have the same or different direction and magnitude as the phase shift for the first component.

Alternatively or additionally, an operation 1610 can be performed. At the operation 1610, a relative phase shift between the first component of the interference pattern and the second component of the interference pattern is determined. The relative phase shift can be determined based on a model of the measurement structure for a specific value of the parameter of interest (e.g., for a zero offset value). The relative phase shift can be determined based on an arbitrary zero or center point for the interference pattern. The relative phase shift can be determined both phase, frequency, amplitude, or a combination thereof of the first component of the interference pattern and the second component of the interference pattern. The relative phase shift can be determined as both a direction and a magnitude. The relative phase shift can have a zero or nonzero direction and magnitude. The relative phase shift can contain information about the difference between the phase shift for the first component of the interference pattern and the phase shift for the second component of the interference pattern.

At an operation 1612, the parameter of interest is determined based on the difference between the phase shift for the first component of the interference pattern and the phase shift for the second component of the interference pattern. The parameter of interest can be determined by comparing the interference pattern to one or more modeled interference patterns which vary with respect to the parameter of interest. The parameter of interest can be determined analytically, such as by using equation as previously described.

As described above, method 1600 (and/or the other methods and systems described herein) is configured to determine a measurement of a parameter of interest in a manufacturing process based on multiple Moiré interference pattern components.

FIG. 17A illustrates an example grating comprising interlaced gratings. The example grating, which can comprise a buried grating or a top grating (e.g., either a first grating or a second grating) is comprises of two interlaced gratings—a first interlaced grating 1720 represented by black rectangles and a second interlaced grating 1730 represented by gray rectangles. The first interlaced grating 1720 and the second interlaced grating 1730 are represented by different shades for illustration only and can comprise the same or a different material. The first interlaced grating 1720 and the second interlaced grating 1730 are also depicted as comprising elements of the same width, but the elements of the first interlaced grating 1720 and the second interlaced grating 1730 can be of different dimensions. The first interlaced grating 1720 and the second interlaced grating 1730 are shown as offset in a z-direction 1704 (along the long axis of the grating elements) and dispersed as a function of pitch in an x-direction 1702. The first interlaced grating 1720 has grating elements which occur at a first interlaced pitch (P1A) 1722. The second interlaced grating 1730 has grating elements which occur at a second interlaced pitch (P1B) 1732. The first interlaced pitch 1722 and the second interlaced pitch 1732 can be different. Elements of the first interlaced grating 1720 and the second interlaced grating 1730 overlap for some values of x in the x-direction 1702. In some cases, depending on the resolution of the detector and on the CD of the grating, the grating elements of the first interlaced grating 1720 and the second interlaced grating 1730 may physically overlap or be instead a single element. A representative diagram 1710 depicts the elements of the example grating which comprises the first interlaced grating 1720 and the second interlaced grating 1730. The example grating can be combined in a measurement structure with an additional grating in order to generate a Moiré interference pattern.

FIG. 17B illustrates an example grating comprising non-overlapping interlaced gratings. The example grating, which can comprise a buried grating or a top grating (e.g., either a first grating or a second grating) is comprises of two interlaced gratings—a first interlaced grating 1770 represented by black lines and a second interlaced grating 1780 represented by gray lines. The first interlaced grating 1770 and the second interlaced grating 1780 are again represented by different shades for illustration only and can comprise the same or a different material. The first interlaced grating 1770 and the second interlaced grating 1780 are also depicted as comprising elements of the same width but can instead comprise elements of different dimensions. The first interlaced grating 1770 and the second interlaced grating 1780 are shown as offset in a z-direction 1754 (along the long axis of the grating elements) and dispersed as a function of pitch in an x-direction 1752. The first interlaced grating 1770 has grating elements which occur at a first interlaced pitch (P1A) 1772. The second interlaced grating 1780 has grating elements which occur at a second interlaced pitch (P1B) 1782. The first interlaced pitch 1772 and the second interlaced pitch 1782 can be different. Elements of the first interlaced grating 1770 and the second interlaced grating 1780 are depicted as non-overlapping for values of x in the x-direction 1702. In some cases, for a sufficiently high resolution or CD for the elements of the grating, the elements of the first interlaced grating 1770 and the second interlaced grating 1780 are non-overlapping or substantially non-overlapping. A representative diagram 1760 depicts the elements of the example grating which comprises the first interlaced grating 1770 and the second interlaced grating 1780. The example grating can be combined in a measurement structure with an additional grating in order to generate a Moiré interference pattern.

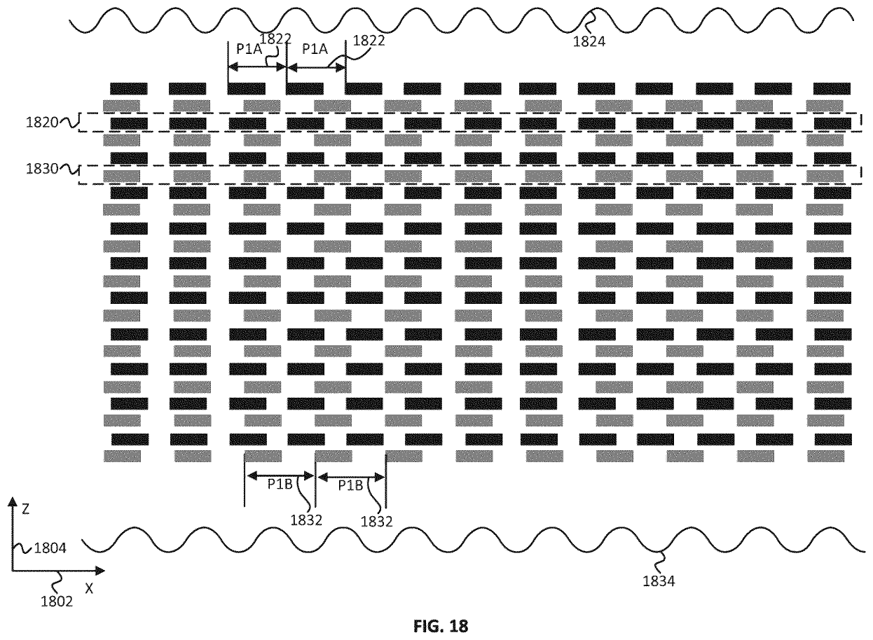

FIG. 18 illustrates an example grating comprising perpendicularly segmented interlaced gratings. The example grating, which can comprise a buried grating or a top grating (e.g., either a first grating or a second grating) is comprises of two interlaced gratings—a first segmented grating 1820 represented by black rectangles and a second segmented grating 1830 represented by gray rectangles. The first segmented grating 1820 and the second segmented grating 1830 are represented by different shades for illustration only and can comprise the same or a different material. The first segmented grating 1820 and the second segmented grating 1830 are also depicted as comprising elements of the same width and height, but the elements of the first segmented grating 1820 and the second segmented grating 1830 can be of different dimensions. The first segmented grating 1820 and the second segmented grating 1830 are shown as segmented into rectangular elements in a z-direction 1804 (along the segmented axis of the grating elements) and dispersed as a function of pitch in an x-direction 1802. The first segmented grating 1820 has grating elements which occur at a first segmented pitch (P1A) 1822. The second segmented grating 1830 has grating elements which occur at a second segmented pitch (P1B) 1832. The first segmented pitch 1822 and the second segmented pitch 1832 can be different. The separation between the elements of the first segmented grating 1820 and the second segmented grating 1830 in the z-direction 1804 is depicted as equal, but can instead asymmetric or otherwise uneven. The elements of the first segmented grating 1820 and the second segmented grating 1830 are shown as separated in the z-direction 1804 but can instead overlap at least partially in the z-direction 1804.

Elements of the first segmented grating 1820 and the second segmented grating 1830 are depicted as distinct for values of x in the x-direction 1802. In some cases, depending on the resolution of the detector and on the CD of the grating, the grating elements of the first segmented grating 1820 and the second segmented grating 1830 may physically overlap in the x-direction 1802, or be instead a single element. A sinusoidal curve 1824 is depicted which represents the frequency and period of the first segmented grating 1820. A sinusoidal curve 1834 is depicted which represents the frequency and period of the second segmented grating 1830. The frequency and period of the grating can be represented by a superposition or sum of the sinusoidal curve 1824, at the first segmented grating 1820, and the sinusoidal curve 1834, at the second segmented grating 1830. The example grating can be combined in a measurement structure with an additional grating in order to generate a Moiré interference pattern.

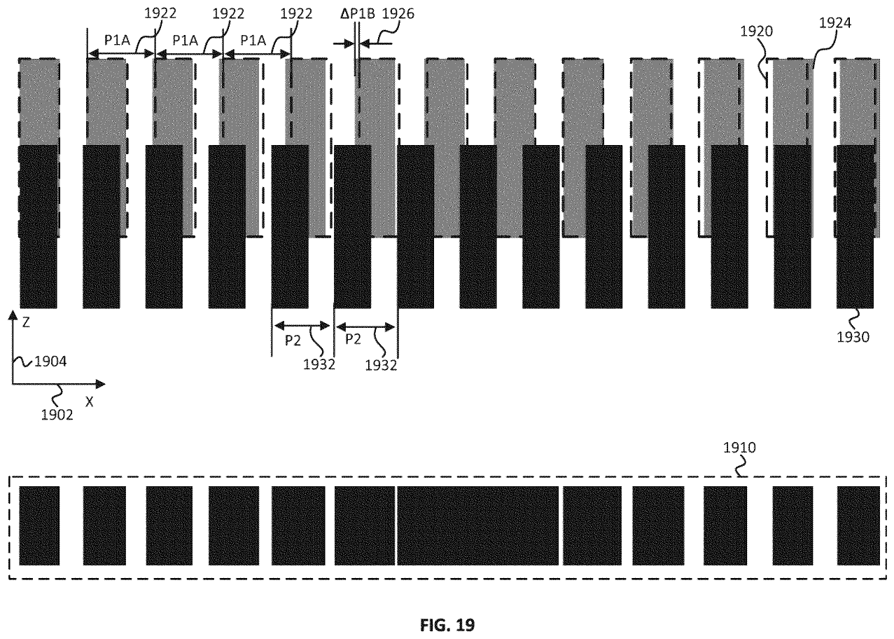

FIG. 19 illustrates an example measurement structure comprising a grating with a varied pitch. The measurement structure is comprised of a varied grating 1924 represented by gray rectangles and a constant grating 1930 represented by black rectangles. The varied grating 1924, which can comprise a buried grating or a top grating (e.g., either a first grating or a second grating) is comprises of a grating varied at two frequencies or over two periods—a first pitch (P1A) 1622 represented by rectangles 1920 outlined by dotted lines and an offset pitch 1926 represented by the offset between the rectangles 1920 and the elements of the varied grating 1924. That is, the placement of the elements of the varied grating 1924 is determined by a first pitch 1922 and the offset pitch 1926. The offset pitch 1926 (e.g., a second pitch) can have a smaller amplitude and a slower frequency that the first pitch 1922. The constant grating 1930 is depicted as a top grating, but can be the buried grating or a top grating. The constant grating 1930 is depicted as having a constant pitch 1932. In some embodiments, the constant grating 1930 can instead have a variable pitch (e.g., can be a varied grating, can be an interlaced grating, etc.). The varied grating of the rectangles 1920 and the constant grating 1930 are represented by different shades for illustration only and can comprise the same or a different material. The varied grating of the rectangles 1920 and the constant grating 1930 are also depicted as comprising elements of the same width, but the elements of the varied grating of the rectangles 1920 and the constant grating 1930 can be of different dimensions. The varied grating of the rectangles 1920 and the constant grating 1930 are shown as offset in a z-direction 1904 (along the long axis of the grating elements) and dispersed as a function of pitch in an x-direction 1902. The offset is for illustration and the grating elements can instead be aligned in the z-direction 1904. The first pitch 1922 and the constant pitch 1932 can be different. A representative diagram 1910 depicts the elements of the example measurement structure which comprises the varied grating of the rectangles 1920 and the constant grating 1930. The combination of the gratings in the measurements structure generates a Moiré interference pattern which can be used to determine overlay offset or other parameters of interest in the manufacturing process.

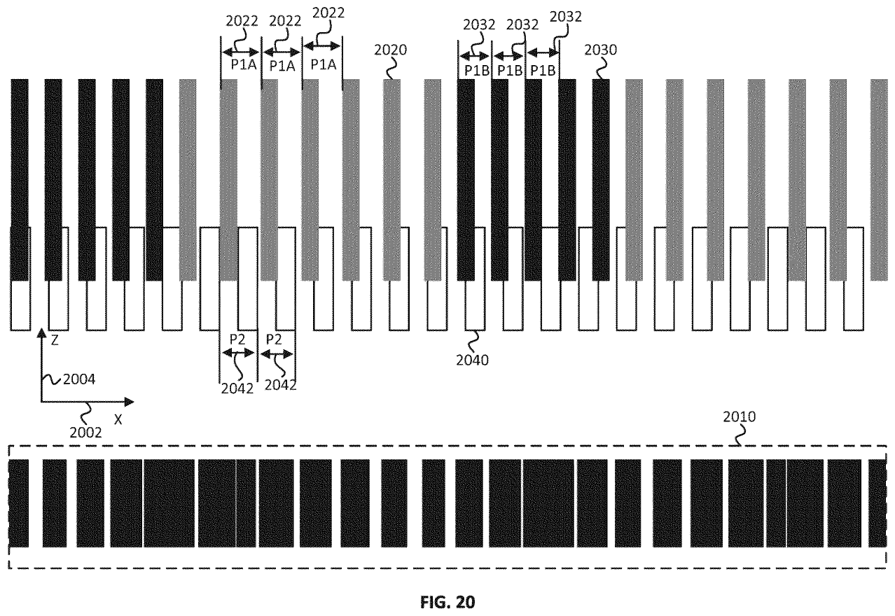

FIG. 20 illustrates an example measurement structure comprising a grating with interspersed areas of different pitches. The interspersed areas can comprise adjacent areas of different pitches. The measurement structure is comprised of a double pitch grating represented by gray rectangles of a first grating 2020 and black rectangles of a second grating 2030 and a constant grating 2040 represented by hashed rectangles. The double pitch grating, which can comprise a buried grating or a top grating (e.g., either a first grating or a second grating) is comprised of sections or areas of the first grating 2020 at a first pitch (P1A) 2022 and of sections of areas of the second grating 2030 at a second pitch (P1B) 2032. The first pitch 2022 and the second pitch 2032 can be different. The first pitch 2022 can be a larger or smaller pitch than the second pitch 2032. The areas of the first grating 2020 and areas of the second grating 2030 are interspersed to comprise the double pitch grating. The areas of the first grating 2020 and the areas of the second grating 2030 are depicted as distinct, but areas of the first grating 2020 and the second grating 2030 could instead be at least partially interlaced or otherwise overlapping. The first grating 2020 and the second grating 2030 are depicted as consisting of elements of substantially the same size. Alternatively, the elements of the first grating 2020 and the second grating 2030 can be different size or of different dimensions. The first grating 2020 and the second grating 2030 are depicted as aligned in a z-direction 2004, but can instead be offset in the z-direction 2004, and the first grating 2020 and the second grating 2030 are depicted as dispersed in a x-direction 2002. Additionally, the double pitch grating is depicted as comprising interspersed areas of two different pitches (e.g., the first grating 2020 and the second grating 2030) but the double pitch grating can instead comprise multiple different pitches (e.g., interspersed areas of three or more pitches). The double pitch grating is depicted as a bottom grating, but can be the top grating or a bottom grating. The first grating 2020 and the second grating 2030 are represented by different shades for illustration only and can comprise the same or different materials.

The constant grating 2040 is depicted as having a constant pitch 2042. In some embodiments, the constant grating 2040 can instead have a variable pitch (e.g., can be a varied grating, can be an interlaced grating, etc.). The double pitch grating and the constant grating 2040 are represented by different shades for illustration only and can comprise the same or different material. The double pitch grating and the constant grating 2040 are also depicted as comprising elements of the same width, but the elements of the double pitch grating and the constant grating 2040 can be of different dimensions. The double pitch grating and the constant grating 2040 are shown as offset in the z-direction 2004 (along the long axis of the grating elements) and dispersed as a function of pitch in an x-direction 2002. The offset is for illustration and the grating elements can instead be aligned in the z-direction 2004. The first pitch 2022, the second pitch 2032 and the constant pitch 2042 can be different. The constant pitch 2042 can comprise a pitch between the first pitch 2022 and the second pitch 2032 in size. A representative diagram 2010 depicts the elements of the example measurement structure which comprises the double pitch grating and the constant grating 2040. The combination of the gratings in the measurements structure generates a Moiré interference pattern which can be used to determine overlay offset or other parameters of interest in the manufacturing process.

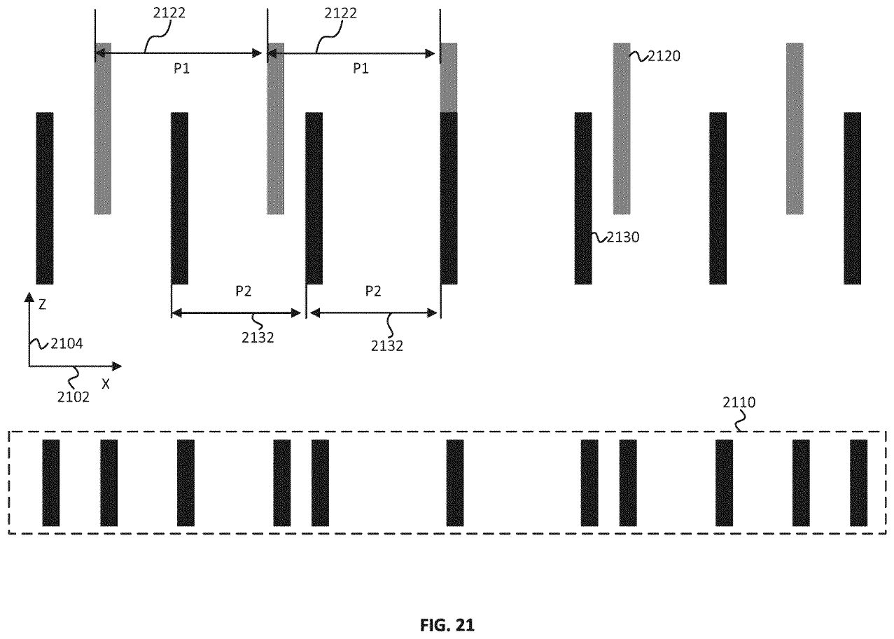

FIG. 21 illustrates an example measurement structure comprising gratings with resolvable pitches. The measurement structure is comprised of a first grating 2120 represented by gray rectangles and a second grating 2130 represented by black rectangles. The first grating 2120, which can comprise a buried grating or a top grating, is comprised periodic elements at a first pitch (P1) 2122. The second grating 2130, which can comprise a buried grating or a top grating (e.g., a grating in the alternative position from the first grating 2120), is comprised of periodic elements at a second pitch (P2) 2132. The first pitch 2122 and the second pitch 2132 can be different. The first pitch 2122 can be a larger or smaller pitch than the second pitch 2132. The elements of the gratings can be smaller than the spaces between the elements, as depicted, or larger than the spaces or substantially the same size. The first grating 2120 and the second grating 2130 are depicted as consisting of elements of substantially the same size. Alternatively, the elements of the first grating 2120 and the second grating 2130 can be different size or of different dimensions. The first grating 2120 and the second grating 2130 are depicted as offset in a z-direction 2104, but can instead be aligned in the z-direction 2104. The first grating 2120 and the second grating 2130 are depicted as symmetric a center point in the x-direction 2102. The first grating 2120 and the second grating 2130 may not be symmetric and may or may not comprise elements which overlap in the z-direction 2104. The first grating 2120 and the second grating 2130 are depicted as having constant pitches, but can instead have variable pitches or multiple pitches as previously described in reference to other figures. The first grating 2120 and the second grating 2130 are represented by different shades for illustration only and can comprise the same or different materials.

The first grating 2120 and the second grating 2130 can have dimensions such that individual components of an interference pattern, which can be a Moiré interference pattern or may be a quasi-Moiré or other interference pattern, can be resolved. In some embodiments, the dimensions of the first pitch 2122 of the first grating 2120 and the second pitch 2132 of the second grating 2130 can be such that individual elements of the measurement structure can be resolved. In some embodiments, this measurement structure can be used for both alignment (e.g., coarse alignment, fine alignment, etc.) and for measurement of an overlay offset or another parameter of interest in the manufacturing process. A representative diagram 2110 depicts the elements of the example measurement structure which comprises the first grating 2120 and the second grating 2130. The combination of the gratings in the measurements structure generates an interference pattern, which may or may not constitute of Moiré interference pattern, which can be used to determine overlay offset or other parameters of interest in the manufacturing process.

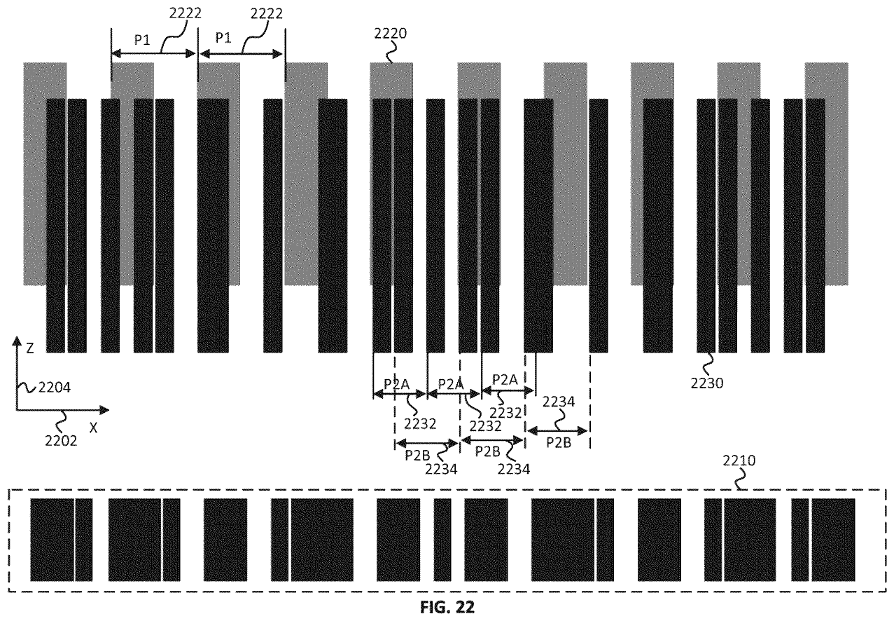

FIG. 22 illustrates an example measurement structure for measurement of a parameter of interest in the manufacturing process based on components of the Moiré interference pattern. The measurement structure can comprise a first grating 2220 and a second grating 2230 (e.g., a buried grating and a top grating where either grating can be located in either position). The first grating 2220 is depicted as a constant pitch grating with a first pitch (P1) 2222. The first grating 2220 can instead be a variable pitch grating, as previously described. The second grating 2230 is comprises of two interlaced gratings or of two pitches—a first interlaced grating with a first interlaced pitch (P2A) 2232 and a second interlaced grating with a second interlaced pitch (P2B) 2234. The elements of the second grating 2230 are the first interlaced pitch 2232 and the second interlaced pitch 2234 are depicted as overlapping or merged—e.g., the overlapping elements at the different pitches can become a single element by overlap. Alternatively, the elements of the first interlaced pitch 2232 and the second interlaced pitch 2234 can be distinct, which can occur for some ranges of electromagnetic signal resolution and CD as previously described in reference to FIG. 17B. The first grating 2220 and the second grating 2230 are represented by different shades for illustration only and can comprise the same or a different material. The first grating 2220 and the second grating 2230 are also depicted as comprising elements of different widths, but the elements of the first grating 2220 and the second grating 2230 can be of substantially the same dimensions. Elements which occur at the first interlaced pitch 2232 and elements with occur at the second interlaced pitch 2234 are depicted as having substantially the same dimensions, but can instead be elements of different or variable dimensions. Overlap of elements of occurring at the first interlaced pitch 2232 and the second interlaced pitch 2234 can contribute to variability in element size. The first grating 2220 and the second grating 2230 are shown as offset in a z-direction 2204 (along the long axis of the grating elements) and dispersed as a function of pitch in an x-direction 2202, but can instead by aligned in the z-direction. A representative diagram 2210 depicts the elements of the example measurement structure which comprises the first grating 2220 and the second grating 2230 which can generate a Moiré interference pattern. The combination of the gratings in the measurements structure generates a Moiré interference pattern which can be used to determine overlay offset or other parameters of interest in the manufacturing process.

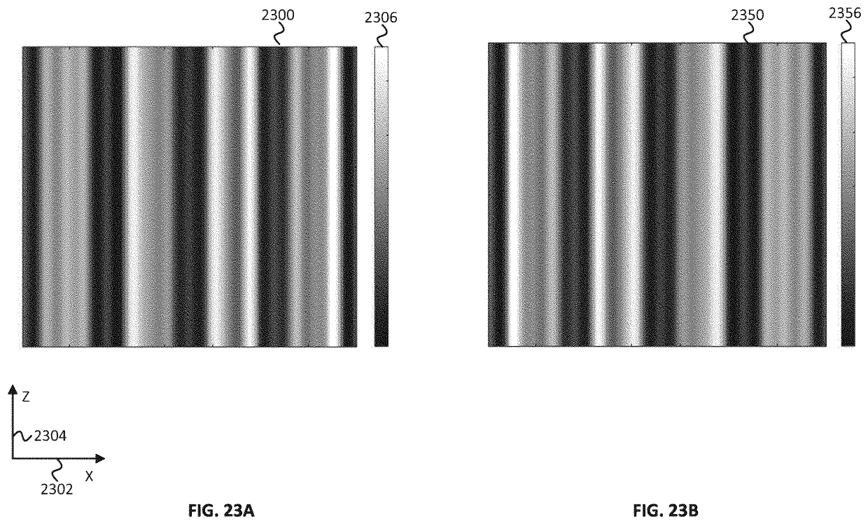

FIGS. 23A and 23B illustrate Moiré interference patterns for the measurement structure of FIG. 22. FIG. 23A displays a graph 2300 which depicts an example Moiré interference pattern for the measurement structure of FIG. 22 for the positive diffraction branch. The intensity of the Moiré interference pattern is depicted as a function of grayscale according to a scale 2306. FIG. 23B displays a graph 2350 which depicts an example Moiré interference pattern for the measurement structure of FIG. 22 for the negative diffraction branch. The intensity of the Moiré interference pattern is depicted as a function of grayscale according to a scale 2356. The intensity of the Moiré interference is depicted as a function of an x direction 2302 and a z direction 2304 of the measurement structure. The scale of the graphs 2300 and 2350 may not be the same as the scale of the FIG. 22. From the Moiré interference patterns of the graphs 2300 and 2350 a measure of overlay offset or another parameter of interest can be determined. The Moiré interference patterns of the graphs 2300 and 2350 display multiple Moiré interference pattern components which correspond to the pitches of the measurement structure, and from which a relationship between the first grating 2220 and the second grating 2230 can be determined.

The example measurement structures provided above are presented as one-dimensional measurement structures. That is, while the measurement structures themselves can have dimensionality or project into all three dimensions (e.g., along the x, y, and z directions as depicted in FIGS. 5-8, 10, 12-14, 17A-17B, and 18-23) each of the previously described structures is substantially unvarying along a direction parallel to the long axis of the grating elements (i.e., along the z-direction as depicted in FIGS. 5-8, 10, 12-14, 17A-17B, and 18-23). The selections of the axis orientations are at least somewhat arbitrary, where for consistency over the figures and description the x-direction has been chosen to correspond to the short axis of the grating elements, the y-direction has been chosen to correspond to an axis substantially perpendicular to at least one of the planes containing the grating elements, and the z-direction has been chosen to correspond to an axis substantially parallel to the long axis of the grating elements for each of the measurement structures depicted. Other axis orientations can be chosen or depicted instead. As the grating elements for a one-dimensional measurement structure have substantially less variation along the z-direction, they are less useful for measuring a parameter of interest which varies in the z-direction than one which varies in the x-direction. However, a measurement structure which varies in two dimensions (e.g., in both the x-direction and z-direction) parallel to the plane of the grating elements can be generated. By extension, the embodiments discussed above can be applied to combination of two or more one dimensional measurement structures, generation of two-dimensional measurement structures, and measurement of parameters of interest based on interference patterns of two-dimensional measurement structures.

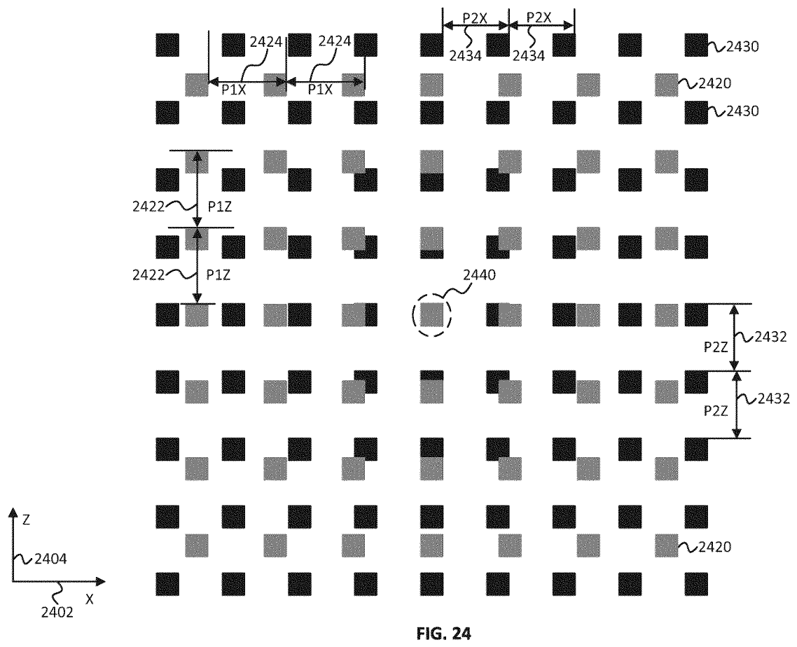

FIG. 24 illustrates an example two-dimensional measurement structure. The measurement structure can comprise a first two-dimensional grating 2420 and a second two-dimensional grating 2430 (e.g., a buried grating and a top grating where either grating can be located in either position). The first two-dimensional grating 2420 and the second two-dimensional grating 2430 are comprised of grating elements which vary in both an x-direction 2402 and a z-direction 2404 (e.g., elements which are arrayed in a two-dimensional plane in the x-direction 2402 and the z-direction 2404.

The first two-dimensional grating 2420 is depicted as a constant pitch grating with a first pitch (P1Z) 2422 in the z-direction 2404 and a second pitch (P1X) 2424 in the x-direction 2402. The first pitch 2422 and the second pitch 2424 are depicted as substantially similar, but may instead be different (including multiples of each other or of a least common denominator). Either or both of the first pitch 2422 and the second pitch 2424 of the first two-dimensional grating 2420 can also or instead be a variable pitch, including a pitch which varies in any manner previously described. The second two-dimensional grating 2430 is depicted as a constant pitch grating with a first pitch (P2Z) 2432 in the z-direction 2404 and a second pitch (P1X) 2434 in the x-direction 2402. The first pitch 2432 and the second pitch 2434 are depicted as substantially similar, but can be different from one another and additionally can be variable pitches as previously described in reference to the first two-dimensional grating 2420.

The first two-dimensional grating 2420 and the second two-dimensional grating 2430 are represented by different shades for illustration only and can comprise the same or a different material. The first two-dimensional grating 2420 and the second two-dimensional grating 2430 are also depicted as comprising elements of substantially the same size in both the x-direction 2402 and the z-direction 2404, but the elements of the first two-dimensional grating 2420 and the second two-dimensional grating 2430 can instead be of different size in one or more dimension or even of variable size in one or more dimension. The first two-dimensional grating 2420 and the second two-dimensional grating 2430 are shown as symmetrical about a center point (indicated by a dotted circle 2440) which is comprised of grating elements of the first two-dimensional grating 2420 and the second two-dimensional grating 2430 which substantially overlap in an y-direction perpendicular to the x-z plane. The first two-dimensional grating 2420 and the second two-dimensional grating 2430 can instead be asymmetric, different symmetry, be symmetric about different points or about a non-centered point, etc. Grating elements of the first two-dimensional grating 2420 and the second two-dimensional grating 2430 may or may not overlap.

The first two-dimensional grating 2420 and the second two-dimensional grating 2430 can generate a two-dimensional interference pattern, such as at a detector, when illuminated by incident radiation. The interference pattern can be or include a Moiré interference pattern. The interference pattern can vary in a direction corresponding to the x-direction 2402 and a direction corresponding to the z-direction 2404. The variations in the interference pattern can be used to determine overlay offset or other parameters of interest in the manufacturing process for the x-direction 2402, the z-direction 2404, or both the x-direction 2402 and the z-direction 2404.

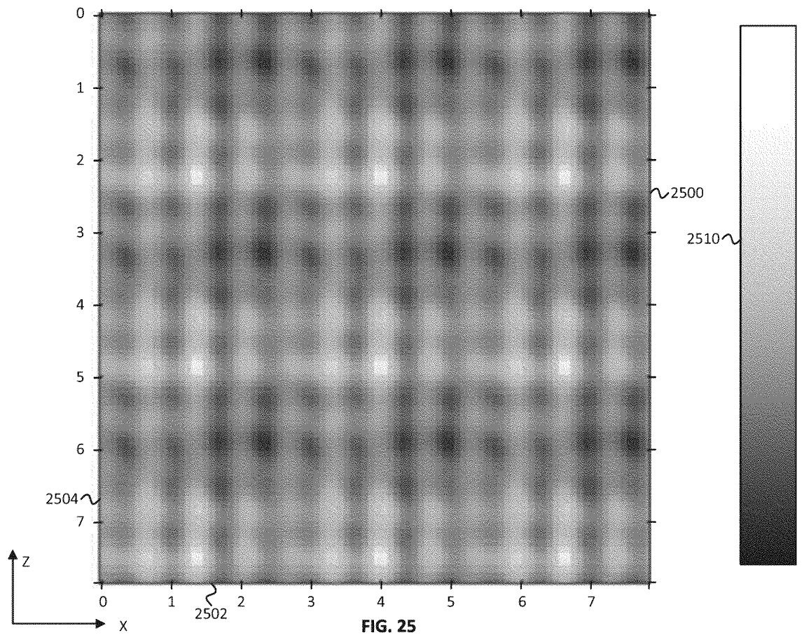

FIG. 25 illustrates a Moiré interference pattern for the measurement structure of FIG. 24. FIG. 25 displays a graph 2500 which depicts an example Moiré interference pattern for the measurement structure of FIG. 24. The intensity of the Moiré interference pattern is depicted as a function of grayscale according to a scale 2510. The intensity of the Moiré interference is depicted as a function of an x-direction along x-axis 2502 and a z-direction along z-axis 2504. The scale of the graph 2500 may not be the same as the scale of the FIG. 22. The intensity of the Moiré interference pattern varies along both the x-axis 2502 and the z-axis 2504. The Moiré interference pattern can be comprised of one or more Moiré interference pattern component which occurs along the x-axis 2502 and one or more Moiré interference pattern component which occurs along the z-axis 2504. The Moiré interference patterns operating along each of the axes can generate additional interference or additive (or subtractive) intensity effects.

From the Moiré interference patterns of the graph 2500 a measure of overlay offset or another parameter of interest can be determined for each of the dimensions. The Moiré interference patterns of the graph 2500 display multiple Moiré interference pattern components in each direction which correspond to the pitches of the measurement structure, and from which a relationship between the first two-dimensional grating 2420 and the second two-dimensional grating 2430 can be determined. A two-dimensional Fourier or other transform can be used to identify components of the interference pattern along each of the dimensions. Based on the identified components, the Moiré interference patterns of each of the dimensions can be deconvolved. Alternatively, Moiré interference pattern components can be extracted individual for each of the dimensions or operated upon together in a two-dimensional frequency space.

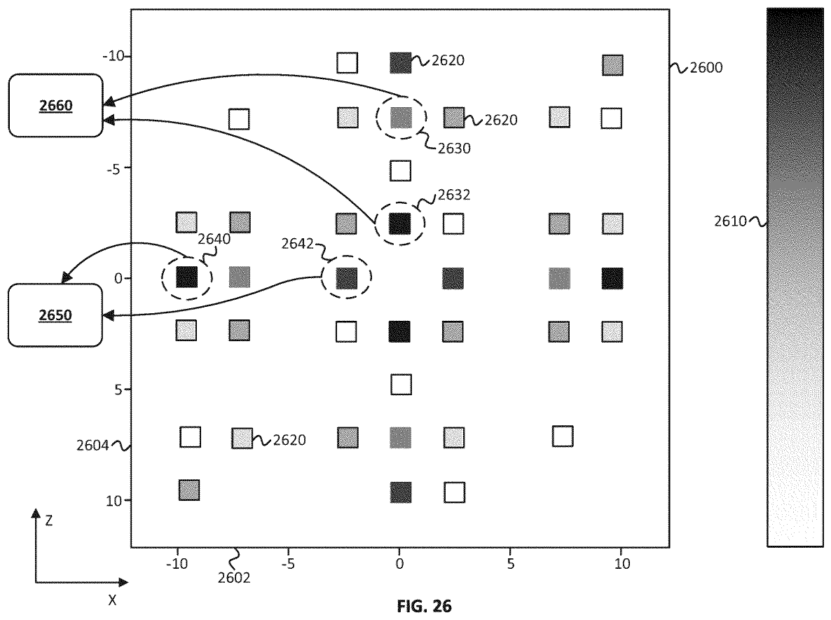

FIG. 26 illustrates a Fourier transform of the Moiré interference pattern of FIG. 25. FIG. 26 displays a graph 2600 which depicts the two-dimensional Fourier transform of the example Moiré interference pattern of FIG. 25. An x-axis 2602 corresponds to values of the Fourier transform of the Moiré interference pattern in the x-direction frequency domain, while a z-axis 2604 corresponds to values of the Fourier transform of the Moiré interference pattern in the z-direction frequency domain. Various components of the interference pattern are apparent in the Fourier transform, where they appear as squares 2620 (which roughly correspond to pixels or groups of pixels). The color of the squares corresponds to the order or component pitch (e.g., the value of m/n for the Moiré interference pattern component X*m/n of the Moiré pitch X). A scale 2610 indicates values of the order (e.g., m/n) to which the component corresponds, where the darker of the squares 2620 correspond to higher values of m/n and the lighter of the squares correspond to lower values of the order (e.g., m/n). The spectrum of the graph 2600 is based on an ideal geometry, which generates sharp, approximately single pixel responses in the Fourier transform. In an acquired image, geometric imperfections can lead to broadening of the peaks of the Fourier transform and leakage of other signals into the image, which can alter the shape of the spectrum in the frequency space. The location and relative positions of the peaks, for even a non-ideal example, can still be used to determine a measurement of a parameter of interest (such as by using center of gravity of the peaks, peak fitting, etc.).

The two-dimensional Fourier transform can separate the components of the interference pattern into components which are generated by interference along each of the directions, as seen in the distribution of the squares 2620. The components for the squares 2620 which lie along a vertical line corresponding to an x value of zero are components which occur due to purely z-direction interference. The components of the squares 2620 which lie along the horizontal line corresponding to a z value of zero correspond to components which occur due to purely x-direction interference. The components which have non-zero values along both the x-axis 2602 and the z-axis 2604 correspond to components which have contributions from both x-direction and z-direction interference. In order to determine a parameter of interest in a manufacturing process, two Moiré components can be selected from the two-dimensional interference pattern. In the graph 2600, for example, the components surrounded by a dotted circle 2630 and a dotted circle 2632 can be compared against each other to determine a parameter of interest 2660, such as overlay, in the y-direction. Likewise, the components surrounded by a dotted circle 2640 and a dotted circle 2642 can be compared against each other to determine a parameter of interest 2650, such as overlay, in the x-direction. The components can optionally be extracted from the interference pattern before being compared.

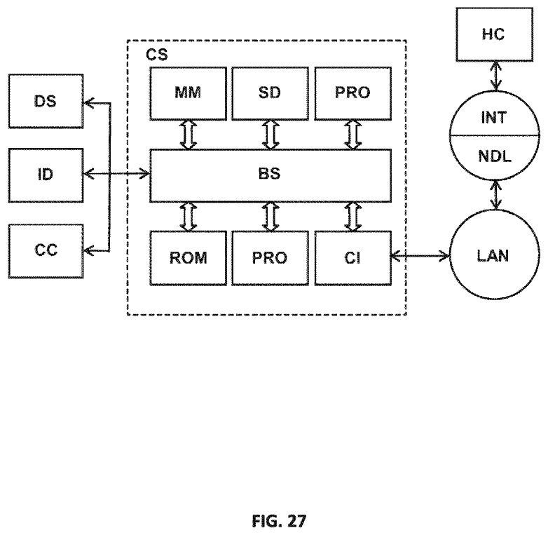

FIG. 27 is a diagram of an example computer system CS that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random-access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” and/or “machine readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Further embodiments according to the invention are described in below numbered clauses:
1. A method comprising: determining, for a measurement structure comprising a first grating with a first pitch and a second grating with a second pitch, a sensitivity of a Moiré interference pattern component with respect to a parameter of interest in a manufacturing process; and evaluating the measurement structure for use in measuring the parameter of interest in the manufacturing process based on the sensitivity.
2. The method of clause 1, wherein the determining of the sensitivity comprises determining a sensitivity as a function of at least one of the first pitch, the second pitch, or a combination thereof.
3. The method of clause 1, wherein the evaluating of the measurement structure comprises: determining if a phase of the Moiré interference pattern component is substantially linear with respect to the parameter of interest in the manufacturing process.
4. The method of clause 1, wherein the evaluating of the measurement structure comprises: determining if a phase of the Moiré interference pattern component is substantially constant with respect to the parameter of interest in the manufacturing process over a range of wavelengths.
5. The method of clause 1, wherein the evaluating of the measurement structure comprises: determining an intensity for the Moiré interference pattern component; and evaluating the measurement structure for measurement of the parameter of interest in the manufacturing process based on the intensity of the Moiré interference pattern component.
6. The method of clause 1, wherein the evaluating of the measurement comprises: evaluating the sensitivity based on absorbance of at least a first material of the measurement structure.
7. The method of clause 1, wherein the Moiré interference pattern component comprises a Moiré interference pattern component at a Moiré pitch.
8. The method of clause 1, wherein the Moiré interference pattern component comprises a Moiré interference pattern component at a pitch smaller than a Moiré pitch.
9. The method of clause 1, wherein the Moiré interference pattern component comprises a Moiré interference pattern component at a pitch larger than a Moiré pitch.
10. The method of clause 1, further comprising: determining a sensitivity of a second Moiré interference pattern component with respect to the parameter of interest in the manufacturing process; and evaluating the measurement structure for use in measuring the parameter of interest in the manufacturing process based on the sensitivity of the second Moiré interference pattern component.
11. The method of clause 10, further comprising: comparing the sensitivity of the Moiré interference pattern component and the sensitivity of the second Moiré interference pattern component; and evaluating the measurement structure for use in measuring the parameter of interest in the manufacturing process based on the comparison.
12. The method of clause 10, further comprising: determining, for the measurement structure, at least one of a phase sensitivity, a phase shift sensitivity, a frequency sensitivity, or a combination thereof with respect to the parameter of interest in the manufacturing process for a relationship between the Moiré interference pattern component and the second Moiré interference pattern component; and evaluating the measurement structure for measurement of the parameter of interest in the manufacturing process based on the at least one of the phase sensitivity, the phase shift sensitivity, the frequency sensitivity, or the combination thereof with respect to the parameter of interest in the manufacturing process for the relationship between the Moiré interference pattern component and the second Moiré interference pattern component.
13. The method of clause 1, wherein the Moiré interference pattern component comprises a Moiré interference pattern component resulting from at least one scattered wavepath.
14. The method of clause 1, wherein the first grating and the second grating are separated by at least a first material with a first refraction index.
15. The method of clause 1, wherein the first grating lies in a first plane and the second grating lies in a second plane, and wherein the first plane and the second plane are offset by a distance substantially perpendicular to the first plane, the second plane, or a combination thereof.
16. The method of clause 1, wherein the first grating lies in a first plane and the second grating lies in a second plane, and wherein the first plane and the second plane are offset by a distance substantially parallel to at least one of the first plane, the second plane, and a combination thereof.
17. The method of clause 1, wherein the determining of the sensitivity of the Moiré interference pattern component with respect to the parameter of interest in the manufacturing process comprises determining the sensitivity based on at least a first material property of the measurement structure.
18. The method of clause 1, wherein the manufacturing process comprises at least one of a lithography process, a depositional process, an etch process, an ion implantation process, or a combination thereof.
19. The method of clause 1, wherein the parameter of interest in the manufacturing process comprises at least one of an overlay offset, an overlay offset error, a measure of focus, a dose, a measure of geometrical variation, a measure of geometric dimension, a measure of symmetry, a measure of asymmetry, or a combination thereof.
20. The method of clause 1, wherein scattered radiation of the measurement structure forms a Moiré interference pattern at a detector when the measurement structure is illuminated by incident radiation.
21. A method comprising: obtaining a Moiré interference pattern for a measurement structure, wherein the measurement structure comprises a first grating at a first pitch in a first layer and a second grating at a second pitch in a second layer; identifying a Moiré interference pattern component in the measured Moiré interference pattern; and determining a measurement of a parameter of interest in a manufacturing process based on the Moiré interference pattern component.
22. The method of clause 21, further comprising: identifying a second Moiré interference pattern component in the Moiré interference pattern; and determining a measurement of the parameter of interest in the manufacturing process based on the Moiré interference pattern component and the second Moiré interference pattern component.
23. The method of clause 22, wherein the determining of the measurement of the parameter of interest in the manufacturing process comprises determining the parameter of interest in the manufacturing process based on at least one of a phase, a phase shift, or a frequency between the Moiré interference pattern component and the second Moiré interference pattern component.
24. The method of clause 22, wherein the Moiré interference pattern component has a different sensitivity to the parameter of interest in the manufacturing process than the second Moiré interference pattern component.
25. The method of clause 22, wherein the Moiré interference pattern component comprises a component of the Moiré interference pattern with a first frequency and wherein the second Moiré interference pattern component comprises a component of the Moiré interference pattern with a second frequency.
26. The method of clause 21, wherein the Moiré interference pattern is at least one of a measured Moiré interference pattern, a simulated Moiré interference pattern, or a combination thereof.
27. A method comprising: determining a Moiré interference pattern component for a measurement structure, wherein the measurement structure comprises a first grating at a first pitch in a first layer and a second grating at a second pitch in a second layer; obtaining a Moiré pattern for the measurement structure; removing the determined Moiré interference pattern component from the Moiré interference pattern; and determining a measure of a parameter of interest in a manufacturing process based on the Moiré pattern with the Moiré interference pattern component removed.
28. The method of clause 27, further comprising: determining a second Moiré interference pattern component for the measurement structure; removing the determined second Moiré interference pattern component from the Moiré pattern; and determining a measure of the parameter of interest in the manufacturing process based on the Moiré pattern with the Moiré interference pattern component and the second Moiré interference pattern component removed.
29. A method comprising: generating parameters for at least one measurement structure, wherein the at least one measurement structure comprises a first grating at a first pitch in a first layer of a multi-layer stack structure and a second grating at a second pitch in a second layer of the multi-layer stack structure, wherein the first pitch and the second pitch are determined based on evaluating the at least one measurement structure for measurement of a parameter of interest in a manufacturing process, wherein the generating of the parameters for the at least one measurement structure comprises, determining, for the at least one measurement structure, a sensitivity of a Moiré interference pattern component with respect to measurement of the parameter of interest in the manufacturing process; and evaluating the at least one measurement structure for use in measuring the parameter of interest in the manufacturing process based on the sensitivity.
30. The method of clause 29, wherein the evaluating of the at least one measurement structure comprises: determining if the sensitivity of the Moiré interference pattern component is substantially linear with respect to the parameter of interest in the manufacturing process; and based on a determination that the sensitivity is substantially linear, conditionally accepting the at least one measurement structure for use in measuring the parameter of interest in the manufacturing process.
31. The method of clause 30, wherein the evaluating of the at least one measurement structure comprises: determining if the sensitivity of the Moiré interference pattern component is substantially constant with respect to the parameter of interest in the manufacturing process over a range of wavelengths; and based on a determination that the sensitivity is substantially constant over a range of wavelengths, conditionally accepting the at least one measurement structure for use in measuring the parameter of interest in the manufacturing process.
32. The method of clause 31, wherein the evaluating of the at least one measurement structure comprises: based on a determination that the sensitivity is not substantially constant over a range of wavelengths, conditionally rejecting the at least one measurement structure for use in measuring the parameter of interest in the manufacturing process.
33. The method of clause 30, wherein the sensitivity of the Moiré interference pattern component comprises at least one of a phase sensitivity, a phase shift sensitivity, a frequency sensitivity, or a combination thereof.
34. The method of clause 30, wherein the evaluating of the at least one measurement structure comprises: based on a determination that the sensitivity is not substantially linear, conditionally rejecting the at least one measurement structure for use in measuring the parameter of interest in the manufacturing process.
35. The method of clause 30, wherein the evaluating of the at least one measurement structure further comprises: determining an intensity of the Moiré interference pattern component; and evaluating the Moiré interference pattern component for use in measuring the parameter of interest in the manufacturing process based on the intensity.
36. The method of clause 35, wherein the evaluating of the at least one measurement structure further comprises: determining if the intensity of the Moiré interference pattern component is substantially less than other Moiré interference pattern components; and based on a determination that the Moiré interference pattern is of substantially less intensity than the other Moiré interference pattern components, conditionally rejecting the Moiré interference pattern component for measurement of the parameter of interest in the manufacturing process.
37. The method of clause 35, wherein the evaluating of the at least one measurement structure further comprises: determining if the intensity of the Moiré interference pattern component is substantially less than other Moiré interference pattern components; and based on a determination that the Moiré interference pattern component is not substantially linear and a determination that the Moiré interference pattern is not of substantially less intensity than the other Moiré interference pattern components, conditionally rejecting the at least one measurement structure for overlay offset measurement.
38. The method of clause 29, wherein the generating of the parameters for the at least one measurement structure further comprises: determining if the evaluation of at least one measurement structure for use in measuring the parameter of interest in the manufacturing process is unfavorable; and based on a determination that the evaluation is unfavorable, adjusting at least one parameter of the at least one measurement structure to generate at least one adjusted measurement structure.
39. The method of clause 38, further comprising: evaluating the at least one adjusted measurement structure, wherein the evaluating of the at least one adjusted measurement structure comprises, determining, for the at least one adjusted measurement structure, a sensitivity of the Moiré interference pattern component with respect to measurement of the parameter of interest in the manufacturing process; and evaluating the at least one adjusted measurement structure for use in measuring the parameter of interest in the manufacturing process based on the sensitivity.
40. The method of clause 38, wherein the determining if the evaluation of the at least one measurement structure for measurement of the parameter of interest in the manufacturing process is unfavorable comprises: determining if the evaluation of the at least one measurement structure for the parameter of interest in the manufacturing process is unfavorable for the Moiré interference pattern component.
41. The method of clause 40, wherein the determining if the evaluation of the at least one measurement structure for measurement of the parameter of interest in the manufacturing process is unfavorable comprises: determining if the evaluation of the at least one measurement structure for the parameter of interest in the manufacturing process is unfavorable for a second Moiré interference pattern component.
42. The method of clause 29, wherein the evaluating of the at least one measurement structure for measurement of the parameter of interest in the manufacturing process further comprises: determining, for the at least one measurement structure, a sensitivity of a second Moiré interference pattern component with respect to measurement of the parameter of interest in the manufacturing process; and evaluating the at least one measurement structure for measurement of the parameter of interest in the manufacturing process based on the sensitivity of the second Moiré interference pattern component.
43. The method of clause 42, wherein the evaluating of the at least one measurement structure further comprises: determining if the sensitivity of the second Moiré interference pattern component is substantially linear with respect to the parameter of interest in the manufacturing process; and based on a determination that the sensitivity of the second Moiré interference pattern component is substantially linear, conditionally accepting the at least one measurement structure for measurement of the parameter of interest in the manufacturing process.
44. The method of clause 43, wherein the evaluating of the at least one measurement structure further comprises: determining if the sensitivity of the second Moiré interference pattern component is substantially constant with respect to the parameter of interest in the manufacturing process over a range of wavelengths; and based on a determination that the sensitivity of the second Moiré interference pattern component is substantially constant over a range of wavelengths, conditionally accepting the at least one measurement structure for measurement of the parameter of interest in the manufacturing process.
45. The method of clause 42, further comprising: obtaining a Moiré interference pattern for the at least one measurement structure; identifying the Moiré interference pattern component in the Moiré interference pattern; identifying the second Moiré interference pattern component in the Moiré interference pattern; and determining a measure of the parameter of interest in the manufacturing process for the at least one measurement structure based on a relationship between the Moiré interference pattern component and the second Moiré interference pattern component.
46. The method of clause 29, wherein the generating of the parameters for the at least one measurement structure comprises: creating the first grating at the first pitch in the first layer of the multi-layer stack; and creating the second grating at the second pitch in the second layer of the multi-layer stack.
47. The method of clause 46, wherein the creating of the first grating comprises at least one of a first photolithography step, a first etch step, a first deposition step, or a combination thereof, and wherein the creating of the second grating comprises at least one of a second photolithography step, a second etch step, a second deposition step, or a combination thereof.
48. The method of clause 46, wherein at least one of the first pitch, the second pitch, or a combination thereof is created by a photolithography mask.
49. The method of clause 46, wherein the creating of the first grating further comprises creating at least a first photolithography mask, and wherein the creating of the second grating comprises creating at least a second photolithography mask.
50. The method of clause 29, wherein the at least one measurement structure is created during a fabrication process in a measurement area on a die.
51. The method of clause 29, wherein the generating of the parameters for the at least one measurement structure comprises: generating at least one mask for generation of the at least one measurement structure based on the parameters.
52. One or more non-transitory, machine readable medium having instructions thereon, the instructions when executed by a processor being configured to perform the method of any of clauses 1 to 51.
53. A system comprising: a processor; and one or more non-transitory, machine-readable medium having instructions thereon, the instructions when executed by the process being configured to perform the method of any of clauses 1 to 51.

While the concepts disclosed herein may be used for manufacturing with a substrate such as a silicon wafer, it shall be understood that the disclosed concepts may be used with any type of manufacturing system (e.g., those used for manufacturing on substrates other than silicon wafers).

In addition, the combination and sub-combinations of disclosed elements may comprise separate embodiments. For example, one or more of the operations described above may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

1. A method comprising:
determining, for a measurement structure comprising a first grating with a first pitch and a second grating with a second pitch, a sensitivity of a Moire interference pattern component with respect to a parameter of interest in a manufacturing process; and
evaluating the measurement structure for use in measuring the parameter of interest in the manufacturing process based on the sensitivity.

2. The method of claim 1, wherein the determining of the sensitivity comprises determining a sensitivity as a function of the first pitch, the second pitch, or both the first and second pitches.

3. The method of claim 1, wherein the evaluating of the measurement structure comprises determining if a phase of the Moire interference pattern component is substantially linear with respect to the parameter of interest in the manufacturing process.

4. The method of claim 1, wherein the evaluating of the measurement structure comprises determining if a phase of the Moire interference pattern component is substantially constant with respect to the parameter of interest in the manufacturing process over a range of wavelengths.

5. The method of claim 1, wherein the evaluating of the measurement structure comprises:
determining an intensity for the Moire interference pattern component; and
evaluating the measurement structure for measurement of the parameter of interest in the manufacturing process based on the intensity of the Moire interference pattern component.

6. The method of claim 1, wherein the evaluating of the measurement comprises evaluating the sensitivity based on absorbance of at least a first material of the measurement structure.

7. The method of claim 1, wherein the Moire interference pattern component comprises a Moire interference pattern component at a Moire pitch.

8. The method of claim 1, wherein the Moire interference pattern component comprises a Moire interference pattern component at a pitch smaller than a Moire pitch.

9. The method of claim 1, wherein the Moire interference pattern component comprises a Moire interference pattern component at a pitch larger than a Moire pitch.

10. The method of claim 1, further comprising:
determining a sensitivity of a second Moire interference pattern component with respect to the parameter of interest in the manufacturing process; and
evaluating the measurement structure for use in measuring the parameter of interest in the manufacturing process based on the sensitivity of the second Moire interference pattern component.

11. The method of claim 10, further comprising:
comparing the sensitivity of the Moire interference pattern component and the sensitivity of the second Moire interference pattern component; and
evaluating the measurement structure for use in measuring the parameter of interest in the manufacturing process based on the comparison.

12. The method of claim 10, further comprising:
determining, for the measurement structure, at least one selected from: a phase sensitivity, a phase shift sensitivity, a frequency sensitivity, or a combination selected therefrom, with respect to the parameter of interest in the manufacturing process for a relationship between the Moire interference pattern component and the second Moire interference pattern component; and
evaluating the measurement structure for measurement of the parameter of interest in the manufacturing process based on the at least one selected from: the phase sensitivity, the phase shift sensitivity, the frequency sensitivity, or the combination selected therefrom, with respect to the parameter of interest in the manufacturing process for the relationship between the Moire interference pattern component and the second Moire interference pattern component.

13. The method of claim 1, wherein the determining of the sensitivity of the Moire interference pattern component with respect to the parameter of interest in the manufacturing process comprises determining the sensitivity based on at least a first material property of the measurement structure.

14. The method of claim 1, wherein the manufacturing process comprises at least selected from: of a lithography process, a depositional process, an etch process, an ion implantation process, or a combination selected therefrom.

15. The method of claim 1, wherein the parameter of interest in the manufacturing process comprises at least one selected from: of an overlay offset, an overlay offset error, a measure of focus, a dose, a measure of geometrical variation, a measure of geometric dimension, a measure of symmetry, a measure of asymmetry, or a combination selected therefrom.

16. One or more non-transitory, machine readable medium having instructions thereon, the instructions when executed by a processor system being configured to cause the processor system to perform at least the method of claim 1.

17. A method comprising:
determining a Moiré interference pattern component for a measurement structure, wherein the measurement structure comprises a first grating at a first pitch in a first layer and a second grating at a second pitch in a second layer;
obtaining a Moiré pattern for the measurement structure;
removing the determined Moiré interference pattern component from the Moiré interference pattern; and
determining a measure of a parameter of interest in a manufacturing process based on the Moiré pattern with the Moiré interference pattern component removed.

18. The method of claim 17, further comprising:
determining a second Moiré interference pattern component for the measurement structure;
removing the determined second Moiré interference pattern component from the Moiré pattern; and
determining a measure of the parameter of interest in the manufacturing process based on the Moiré pattern with the Moiré interference pattern component and the second Moiré interference pattern component removed.

19. The method of claim 17, wherein the parameter of interest in the manufacturing process comprises at least one selected from: an overlay offset, an overlay offset error, a measure of focus, a dose, a measure of geometrical variation, a measure of geometric dimension, a measure of symmetry, a measure of asymmetry, or a combination selected therefrom.

20. One or more non-transitory, machine readable medium having instructions thereon, the instructions when executed by a processor system being configured to cause the processor system to perform at least the method of claim 17.
